(19) United States
(12) Patent Application Publication
(10) Pub. No.: US 2026/0271362 A1
(43) Pub. Date: Sep. 10, 2026

(54) BACKSIDE HARD MASKS TO FORM SELF-ALIGNED BACKSIDE VIAS

(71) Applicant: Taiwan Semiconductor Manufacturing Company, Ltd., Hsin-Chu (TW)

(72) Inventors: Yu-Chun Lin, Hsinchu (TW); Po-Yu Huang, Hsinchu (TW); Chen-Ming Lee, Yangmei City (TW); I-Wen Wu, Hsinchu City (TW); Mei-Yun Wang, Chu-Pei City (TW)

(21) Appl. No.: 19/069,526

(22) Filed: Mar. 4, 2025

(51) Int. Cl. H10D 64/23; H01L 21/768; H10D 30/00; H10D 30/01; H10D 30/47; H10D 62/10; H10D 64/01; H10D 84/01; H10D 84/85

(52) U.S. Cl. CPC H10D 64/251; H10D 30/014; H10D 30/0191; H10D 30/47; H10D 30/503; H10D 62/121; H10D 64/017; H10D 84/0167; H10D 84/017; H10D 84/0186; H10D 84/0188; H10D 84/851; H10W 20/069

(57) ABSTRACT

One aspect of the present disclosure pertains to a method of forming a semiconductor device. The method includes forming a semiconductor stack with interleaved first and second semiconductor layers over a substrate; patterning the semiconductor stack and the substrate to form semiconductor fins having semiconductor stack portions over base portions; depositing an isolation layer over the semiconductor fins; and recessing the isolation layer to form an isolation structure laterally surrounding bottom portions of the semiconductor fins and exposing top portions of the semiconductor fins, wherein the bottom portions include dummy semiconductor layers buried in the isolation structure.

### CROSS-REFERENCE TO RELATED APPLICATIONS

This application is related to the U.S. patent application with Attorney Docket No. 24061.5059US01, the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As feature sizes continue to decrease, some IC features such as source/drain metal contacts and power line connections may be moved to the back side of the wafer. Moving these features allows for better spacing management while optimizing power consumption. To achieve this, source/drain features formed on the front side of the substrate must electrically connect to backside power rails through backside vias (or backside metal contacts). These backside vias need to have low resistance, low capacitance, and low leakage current for improved device performance. In some cases, leakage current becomes an issue when the backside vias are not properly insulated. For example, there may be current leakage through inner metal gate to the backside vias due to overlay shift errors during backside processing. The overlay shift errors may be the result of wafer warpage and strain caused by frontside processes and/or wafer flip and bonding processes.

Therefore, although existing methods of forming backside vias have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor structure having a buried dummy semiconductor layer below an isolation structure, in portion or in entirety, according to an embodiment of the present disclosure.

FIGS. 2-4, 5A, and 5B illustrates cross-sectional views of a semiconductor device at intermediate stages of fabrication and processed in accordance with the method of FIG. 1, according to an embodiment of the present disclosure.

FIGS. 6A-6B illustrates a flow chart of a method to form a semiconductor structure having a self-aligned backside via, in portion or in entirety, according to an embodiment of the present disclosure.

FIG. 7 illustrates a three-dimensional view of a semiconductor workpiece having a buried dummy semiconductor layer below an isolation structure and with lines A-A′, B-B′, and C-C′ cut across the workpiece.

FIGS. 8A, 9A, 10A, 11A, 12A, 13A, 14A, 15A, 16A, 17A, 18A, 19A, 20, 21, 22, 23, and 24 illustrate cross-sectional views of a semiconductor device cut along the lines A-A′ in FIG. 7 at intermediate stages of fabrication and processed in accordance with the method of FIGS. 6A-6B, according to an embodiment of the present disclosure.

FIGS. 8B, 9B, 10B, 11B, 12B, 13B, 14B, 15B, 16B, 17B, 18B, 19B illustrate cross-sectional views of a semiconductor device cut along the lines B-B′ in FIG. 7 at intermediate stages of fabrication and processed in accordance with the method of FIGS. 6A-6B, according to an embodiment of the present disclosure.

FIGS. 8C, 9C, 10C, 11C, 12C, 13C, 14C, 15C, 16C, 17C, 18C, 19C illustrate cross-sectional views of a semiconductor device cut along the lines C-C′ in FIG. 7 at intermediate stages of fabrication and processed in accordance with the method of FIGS. 6A-6B, according to an embodiment of the present disclosure.

FIGS. 25A, 25B, 25C, and 26 illustrate the formation of a semiconductor device having a self-aligned backside vias according to another embodiment of the present disclosure.

FIGS. 27-30 illustrate various embodiments of a semiconductor device having a self-aligned backside via using backside hard masks.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself limit the relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor devices having backside hard masks for forming self-aligned backside vias. Without a self-aligned process, the backside vias are formed with overlay shifts that may cause current leakage and parasitic coupling between the backside vias and the nearby metal gates, which degrades device performance and causes yield loss. The present disclosure addresses this and other issues by forming backside hard masks that cover backsides of the metal gates; the backside vias are then formed through a self-aligned process using the backside hard masks as etch masks. The backside hard masks are formed by forming an extra dummy semiconductor layer buried below a semiconductor stack. The dummy semiconductor layer is converted into a dummy dielectric while the semiconductor stack is converted into semiconductor channels wrapped around by metal gate(s). After the semiconductor device is flipped for backside processing, the dummy dielectric serves as a high-quality hard mask for forming self-aligned backside vias. In this way, the process window of forming backside vias is improved (i.e., overlay shift becomes acceptable within margins). Further, due to hard mask protection blocking the metal gates, the backside vias may be formed larger such that the critical dimension of a bottom portion of the backside vias is greater than a critical dimension of a top portion of the backside vias.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

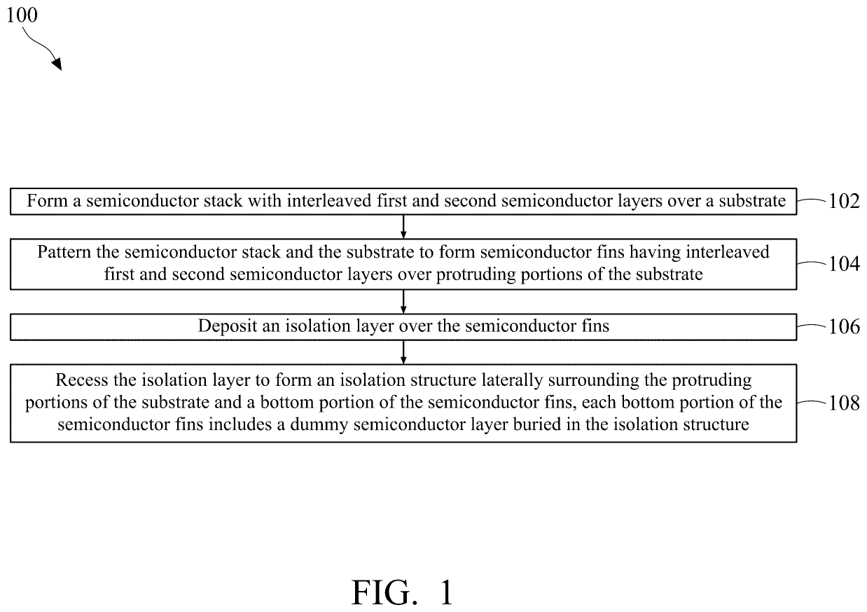

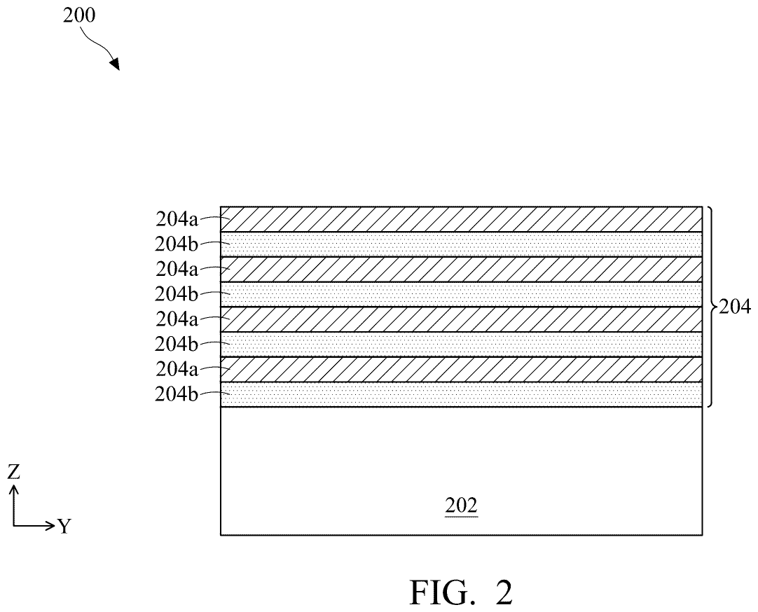

FIG. 1 illustrates a flow chart of a method 100 to form a semiconductor structure having a buried dummy semiconductor layer below an isolation structure, in portion or in entirety, according to an embodiment of the present disclosure. The buried dummy semiconductor layer will later be replaced with a dielectric interposer, which will act as a backside hard mask. The semiconductor structure corresponds to a semiconductor device (or portions thereof), and the two terms may be used interchangeably. FIGS. 2-4, 5A, and 5B illustrates cross-sectional views of a semiconductor device 200 at intermediate stages of fabrication and processed in accordance with the method 100 of FIG. 1, according to an embodiment of the present disclosure. The method 100 is described below with reference to FIGS. 2-4, 5A, and 5B. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

The semiconductor device 200 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

Referring now to FIG. 2, the method 100 at operation 102 begins forming a semiconductor device 200 by forming a semiconductor stack 204 over a substrate 202. The substrate 202 may be a silicon (Si) substrate, or a substrate having other semiconductor materials such as germanium (Ge), silicon carbide (SiC), silicon germanium (SiGe), or diamond. The substrate 202 may be undoped. Alternatively, the substrate 202 may be doped with a p-type dopant such as boron or an n-type dopant such as phosphorus (e.g., to form a p-type well and an adjacent n-type well). In a further embodiment, the substrate 202 may be doped with nitrogen for growing defect-free silicon crystal stacks (e.g., semiconductor stack 204) or defect-free silicon crystal source/drain features (e.g., source/drain features 800 later described). The semiconductor stack 204 is then epitaxially grown over the substrate 202. The semiconductor stack 204 includes interleaved first and second semiconductor layers 204a and 204b. The present embodiment illustrates four first semiconductor layers 204a and four second semiconductor layers 204b but the present disclosure is not limited thereto. For example, there may be any appropriate number of layers in the semiconductor stack 204. For example, there may be 2 to 10 layers of first semiconductor layers 204a, alternating with 2 to 10 layers of second semiconductor layers 204b in the semiconductor stack 204. The first semiconductor layers 204a have a different material composition than the second semiconductor layers 204b. For example, each of the first semiconductor layers 204a is made of silicon and each of the second semiconductor layers 204b is made of silicon germanium. In an embodiment, the silicon and/or silicon germanium of the first and the second semiconductor layers 204a and 204b are undoped while the substrate 202 is doped. In other embodiments, the silicon and/or silicon germanium of the first and the second semiconductor layers 204a and 204b are also doped, such as via in-situ doping. In the present embodiment, the substrate 202 and the first semiconductor layers 204a include similar material compositions (e.g., both are made of silicon).

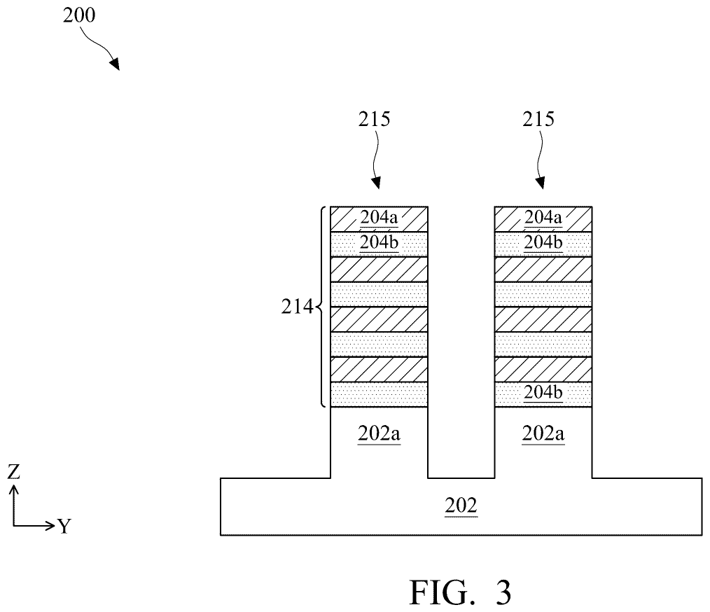

Referring now to FIG. 3, the method 100 at operation 104 patterns the semiconductor stack 204 and the substrate 202 to form semiconductor fins 215. Each of the semiconductor fins 215 includes a protruding portion 202a of the substrate 202 and a semiconductor stack portion 214 of the semiconductor stack 204. The protruding portions 202a may be referred to as base portions of the semiconductor fins 215, and the semiconductor stack portion 214 may be referred to as semiconductor stack portions of the semiconductor fins 215. The semiconductor fins 215 may be formed by a patterning process that includes lithography and etching. In some embodiments, a lithography process forms a patterned mask layer that cover regions for forming the semiconductor fins 215, and an etching process uses the patterned mask layer as an etch mask to etch exposed portions of the patterned mask layer. The etching process forms recesses (or trenches) that separate and define the semiconductor fins 215.

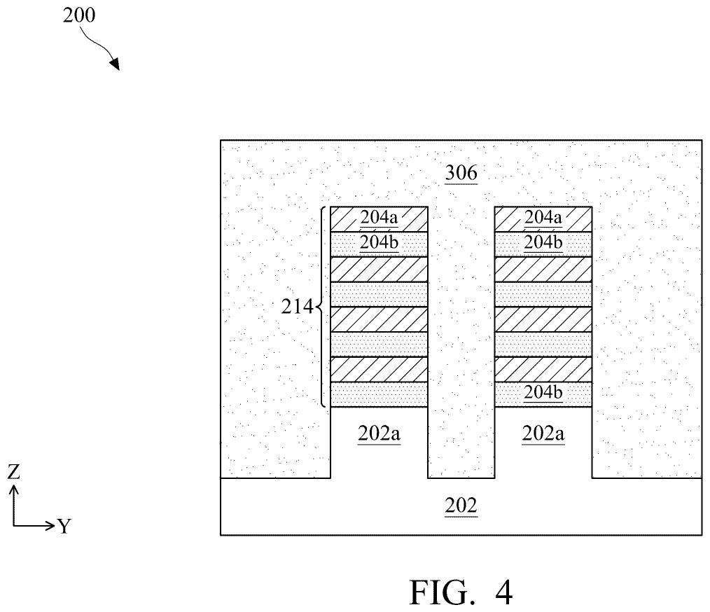

Referring to FIG. 4, the method 100 at operation 106 deposits an isolation layer 306 over the semiconductor fins 215. The isolation layer 306 lands on a top surface of the substrate 202, fills in the recesses between the semiconductor fins 215, and lands on a top surface of the semiconductor fins. In other words, the isolation layer 306 is overfilled to surround all exposed surfaces of the semiconductor fins 215. The isolation layer 306 may be deposited by any suitable deposition process such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof. The isolation layer 306 may include silicon oxide, silicon oxynitride, fluorine-doped silicate glass (FSG), a low-k dielectric, combinations thereof, and/or other suitable materials. In an embodiment, the isolation layer 306 includes an oxide-based dielectric such as silicon oxide. In another embodiment, the isolation layer 306 includes a non-oxide-based dielectric such as silicon carbide, silicon oxynitride, or silicon carbonitride.

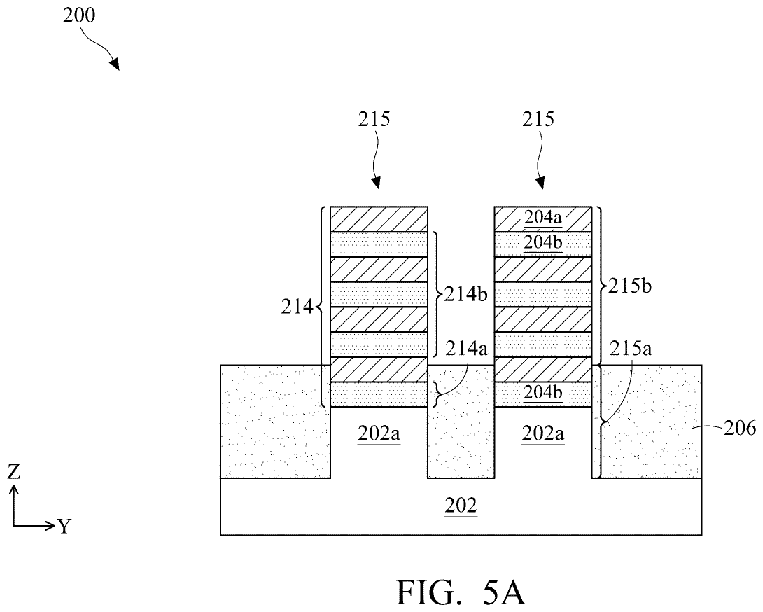

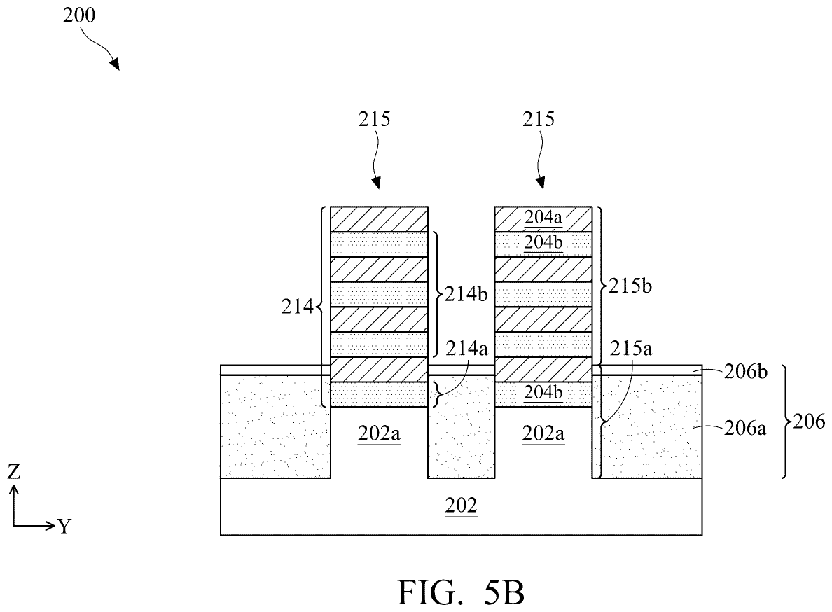

Referring to FIG. 5A, the method 100 at operation 108 recesses the isolation layer 306 to form an isolation structure 206 laterally surrounding bottom portions 215a of the semiconductor fins 215 and exposing top portions 215b of the semiconductor fins 215. The bottom portions 215a refer to portions that will not be used to form semiconductor channels (i.e., dummy portions) and the top portions 215b refer to portions that will be used to form semiconductor channels (i.e., functional portions). Each bottom portion 215a includes a protruding portion 202a of the substrate 202 and a bottommost second semiconductor layer 204b buried in the isolation structure 206. This buried bottommost second semiconductor layer 204b is also referred to as a dummy semiconductor layer 214a or a dummy sheet 214a. As described in further detail below, the dummy sheet 214a will be converted into a backside dielectric hard mask for forming self-aligned backside vias. Each top portion 215b includes exposed first and second semiconductor layers 204a and 204b of the semiconductor stack portion 214. These exposed first and second semiconductor 204a and 204b are also referred to as functional semiconductor layers 214b or functional sheets 214b.

Still referring to FIG. 5A, the isolation structure 206 may be formed by first performing a Chemical Mechanical Polish (CMP) to remove excess portions of the isolation layer 306 over top surfaces of the semiconductor fins 215. The remaining portions of the isolation layer 306 form isolation regions laterally between semiconductor fins 215. Next, the isolation regions are recessed in an etching step, so that the top portions 215b of the semiconductor fins 215 are over the top surfaces of the isolation regions. The resulting isolation regions form the isolation structure 206. In the present embodiment, the isolation structure 206 is a shallow trench isolation (STI) structure. Importantly, the isolation structure 206 should have a top surface that is above a top surface of the dummy sheets 214a, thereby covering and embedding the dummy sheets 214a. On the other hand, the isolation structure 206 should not cover the functional sheets 214b. In the embodiment shown, the STI boundary (i.e., top surface of the isolation structure 206) is somewhere between a top surface of the dummy sheet 214a and a bottom surface of the bottommost second semiconductor layer 204b of the functional sheets 214b. In this way, after the dummy sheets 214a are replaced with bottom interposers in a later step, the isolation structure 206 is sure to protect the bottom interposers from being etched away while the exposed functional sheets 214b are processed. The bottom interposers remain as backside hard masks for forming self-aligned backside vias. Notably, the isolation structure 206 has a different dielectric material from the later-formed bottom interposer-this is to provide etchant selectivity to protect the bottom interposer from being etched while top interposers are etched away. For example, if the later-formed bottom and top interposers are made of silicon oxide, the isolation structure 206 includes a non-oxide-based dielectric such as silicon carbide, silicon oxynitride, or silicon carbonitride. For another example, if the later-formed bottom and top interposers are made of a BARC material or a non-oxide-based dielectric, the isolation structure 206 includes silicon oxide or other oxide-based dielectric.

FIG. 5B illustrates an alternative embodiment of forming the isolation structure 206. In FIG. 5A, the recessed portion of the isolation layer 306 simply forms the isolation structure 206. Whereas in FIG. 5B, the isolation structure 206 includes both a recessed portion 206a of the isolation layer 306 and a hard mask structure 206b formed thereover. The recessed portion 206a and the hard mask structure 206b may be referred to as a distinct isolation structure 206a and a distinct hard mask structure 206b respectively, or they may be collectively referred to as different portions of a larger isolation structure 206. Notably, the hard mask structure 206b includes a different dielectric material from the recessed portion 206a to achieve desired etching selectivity and/or to achieve different isolation effects (e.g., to protect the recessed portion 206a from being etched in later fabrication steps). For example, a material of the hard mask structure 206b is selected such that it protects the recessed portion 206a from being etched when etching dielectric interposers having a same material as that of the recessed portion 206a. In an embodiment, the hard mask structure 206b is deposited by CVD and includes silicon nitride, silicon oxynitride, silicon carbide, silicon oxycarbide, or silicon oxycarbonitirde. In an embodiment, the recessed portion 206a includes silicon oxide and the hard mask structure 206b includes silicon nitride. In the depicted embodiment, both top surfaces of the hard mask structure 206b and the recessed portion 206a is formed above a top surface of the dummy sheets 214a. However, in other embodiments, the recessed portion 206a may be formed coplanar or below a top surface of the dummy sheets 214a as long as the top surface of the hard mask structure 206b is formed above the top surface of the dummy sheets 214a.

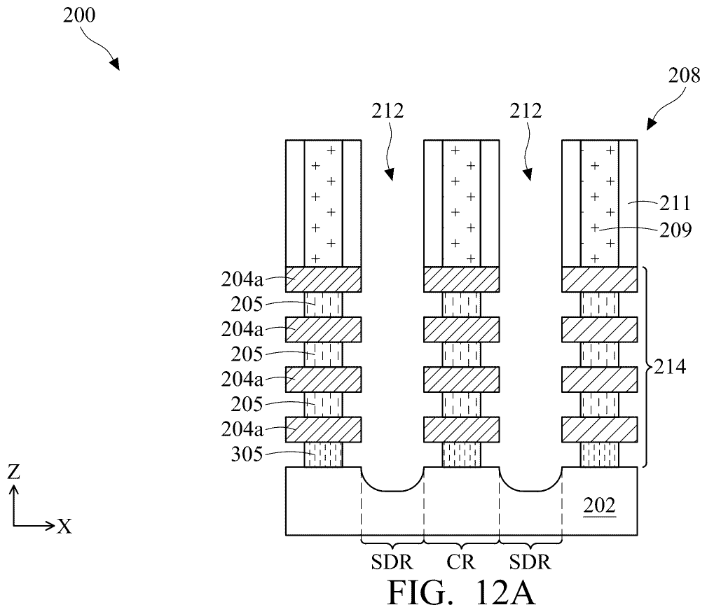

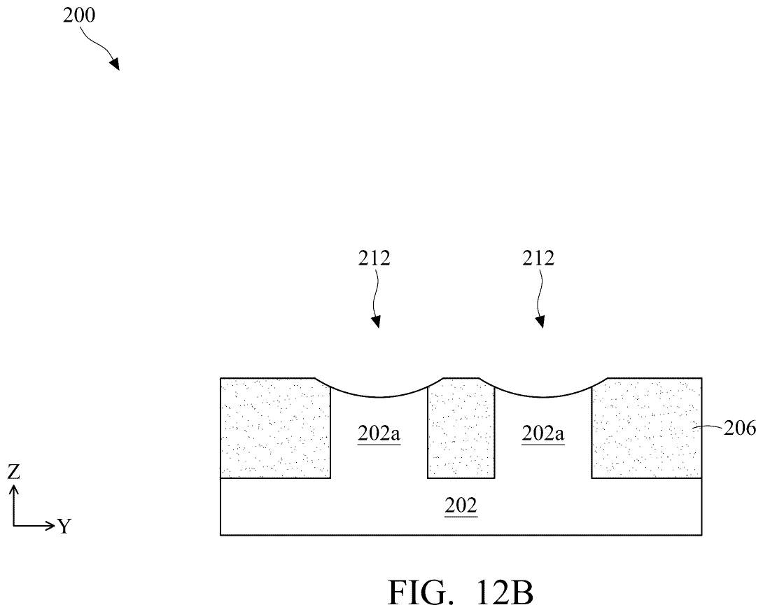

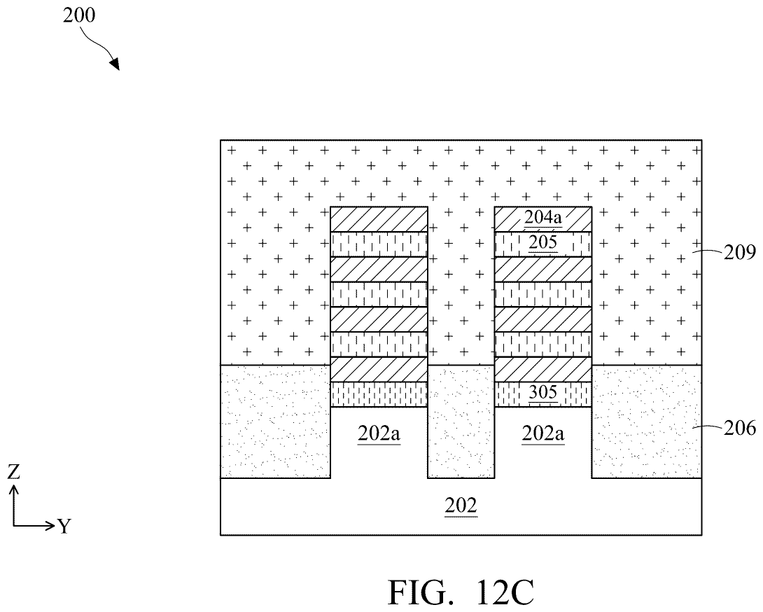

Comparing the embodiment of FIG. 5A and the embodiment of FIG. 5B, each have their own advantages. In the embodiment of FIG. 5A, manufacturing costs associated with forming a hard mask is eliminated. Further, manufacturing steps are also reduced (no need to deposit hard mask material, perform planarization, etch-back, etc.). However, due to etching selectivity requirements, the embodiment of FIG. 5A will have more stringent process windows in selecting the appropriate dielectric materials for the isolation structure 206 and/or the later-formed interposer layers 205 and 305 (see FIGS. 12A-12C). In the embodiment of FIG. 5B, due to formation of the hard mask structure 206b, there is a more relaxed process window in selecting dielectric materials for the isolation structure 206a. For example, the isolation structure 206a and the later-formed interposer layers may include same dielectric materials because the hard mask structure 206b provides the necessary etchant selectivity for etchant protection. However, the embodiment of FIG. 5B incurs additional costs associated with forming the hard mask structure 206b.

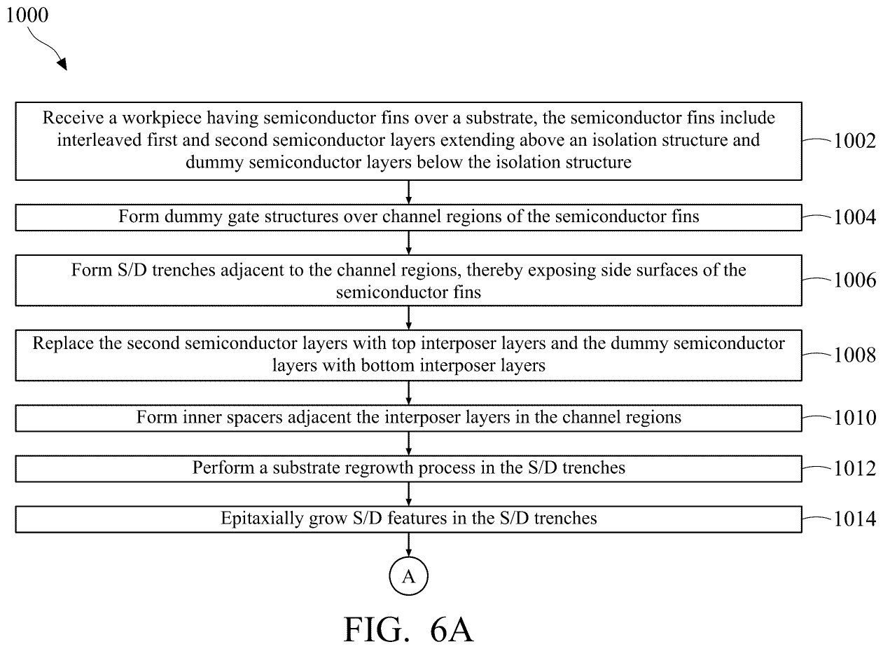

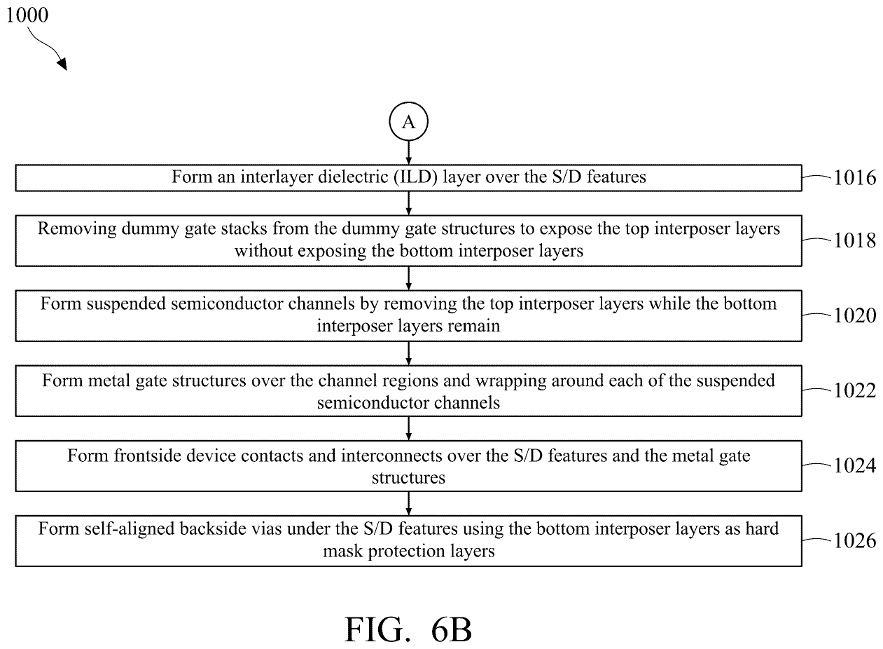

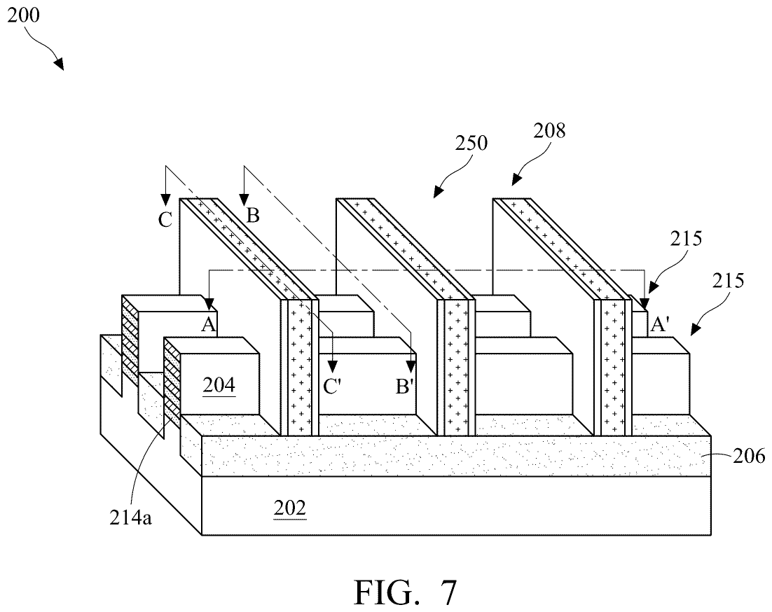

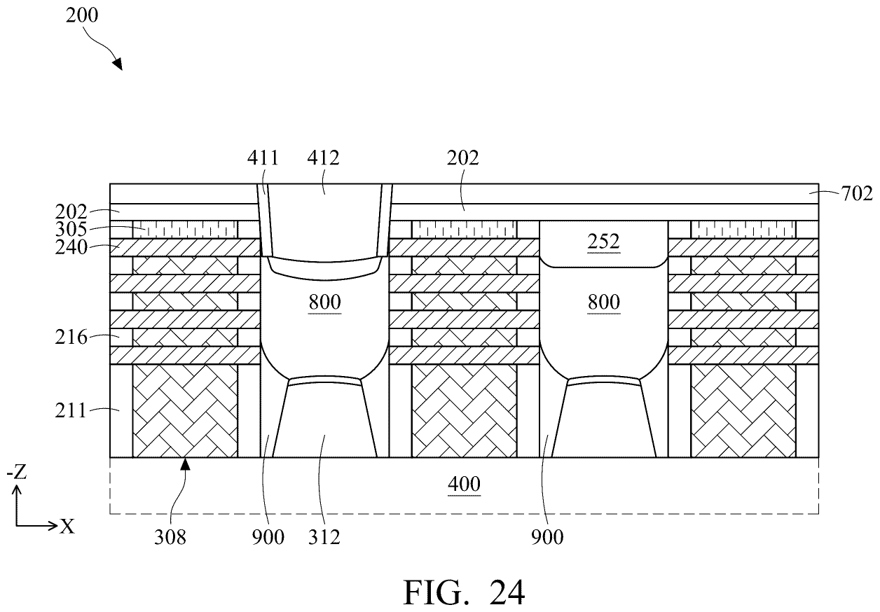

FIGS. 6A-6B illustrates a flow chart of a method 1000 to form a semiconductor structure 200 having a self-aligned backside via 412 (see e.g., FIG. 24), in portion or in entirety, according to an embodiment of the present disclosure. In an embodiment, the semiconductor device 200 at the end of method 100 is received at the beginning of method 1000, and the received semiconductor device 200 continues to be processed according to the method 1000. The method 1000 is described below with reference to FIGS. 7, 8A-19A, 8B-19B, 8C-19C, and 20-24. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

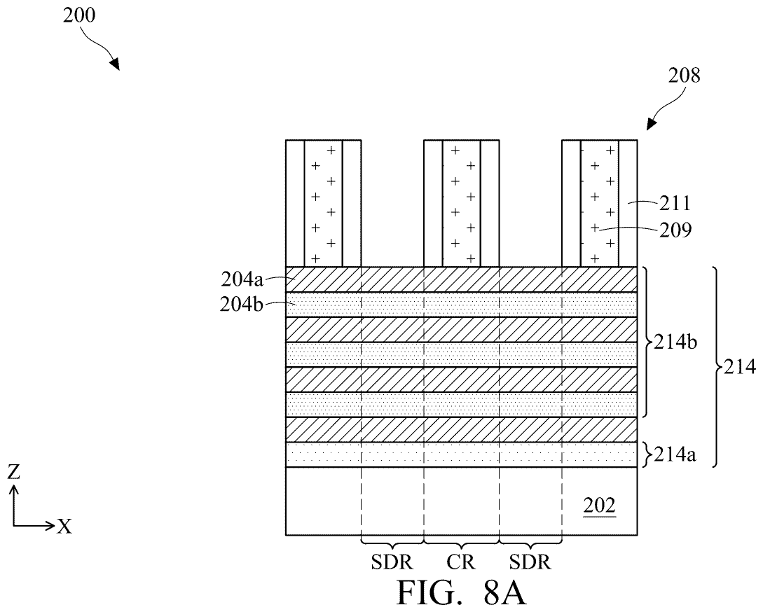

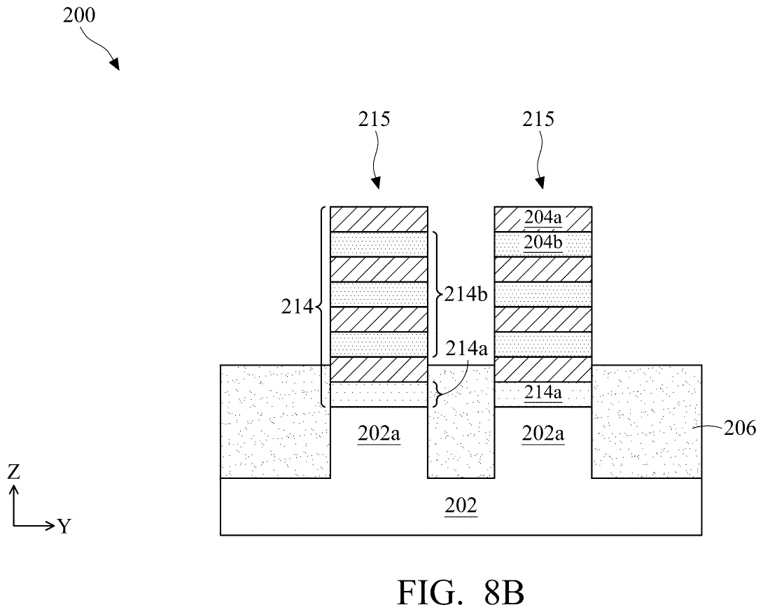

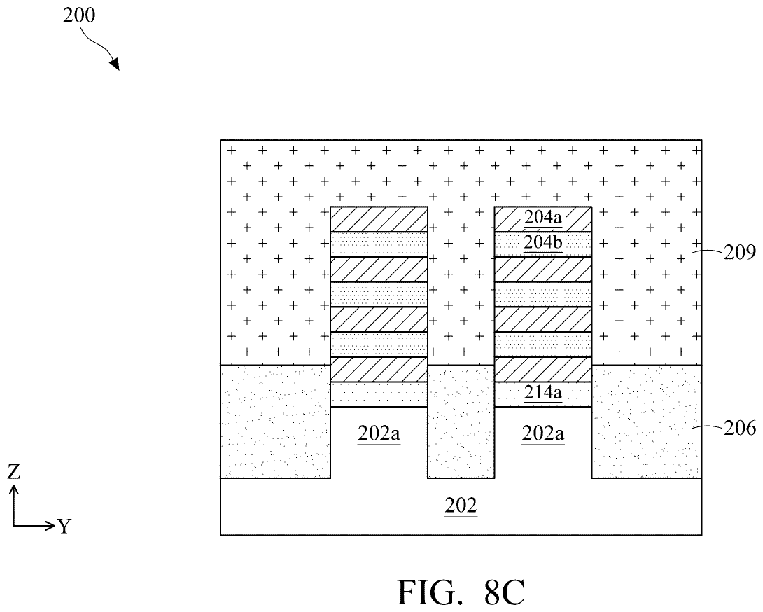

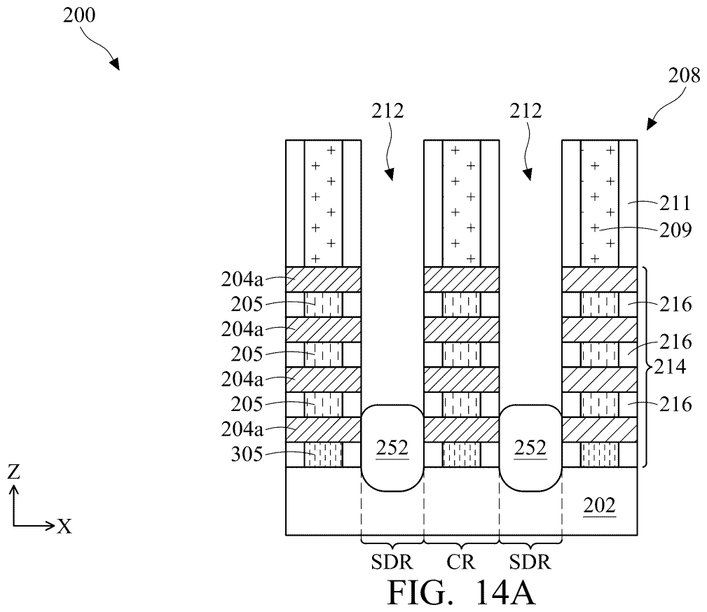

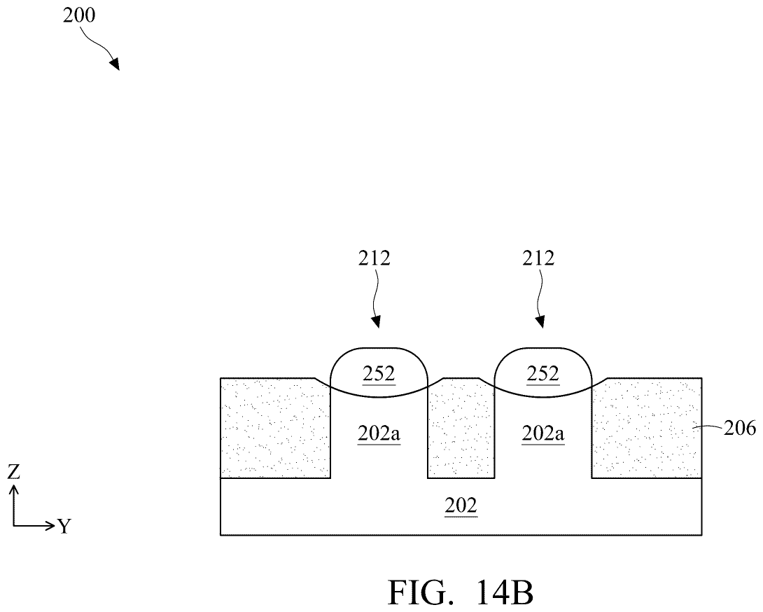

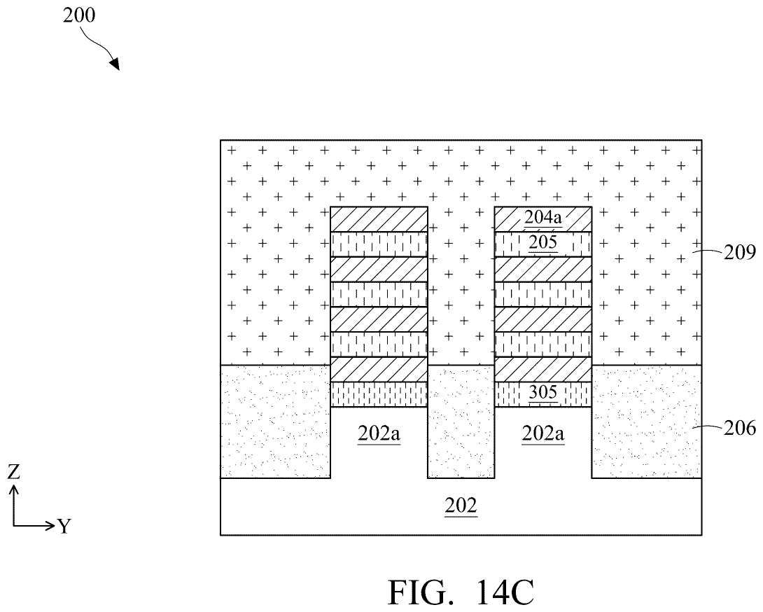

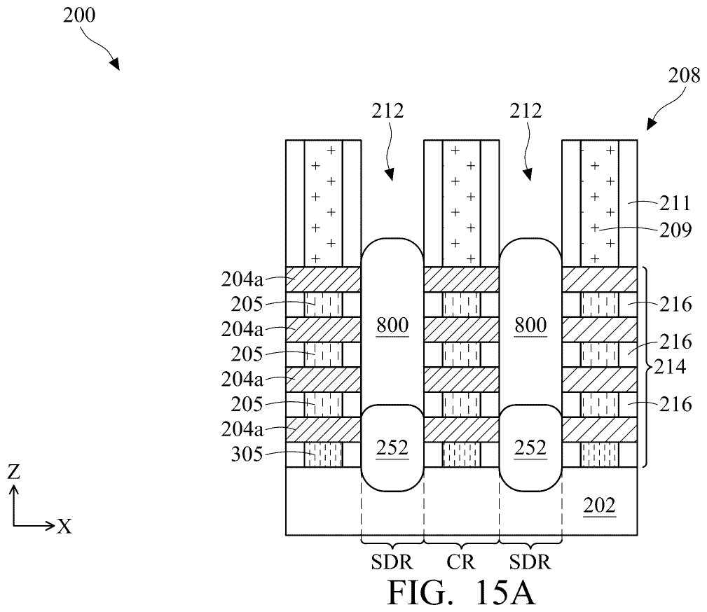

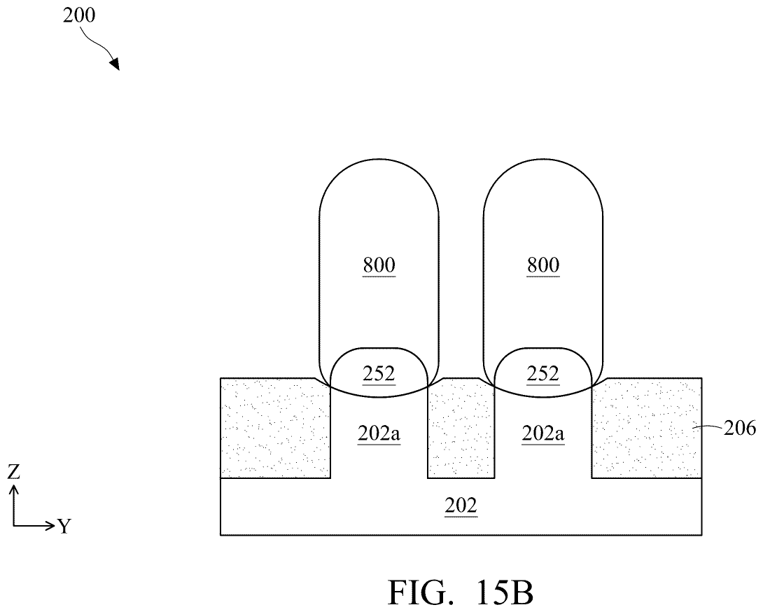

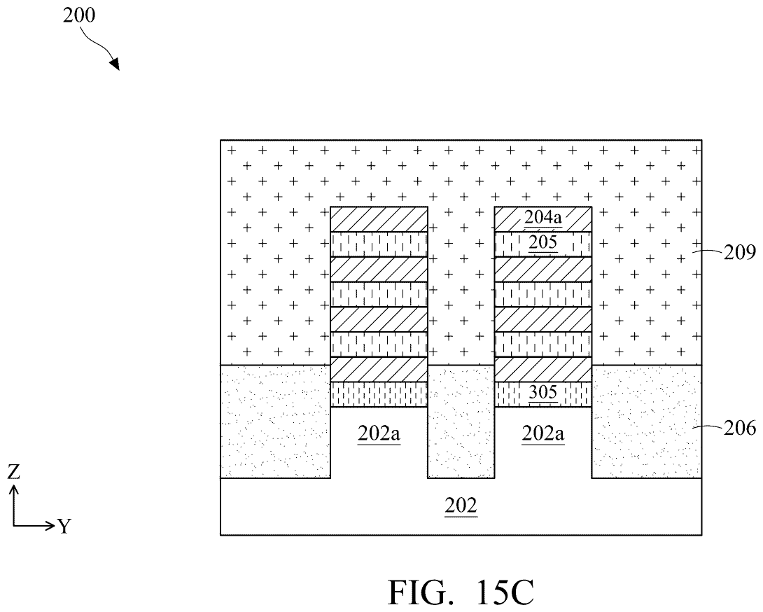

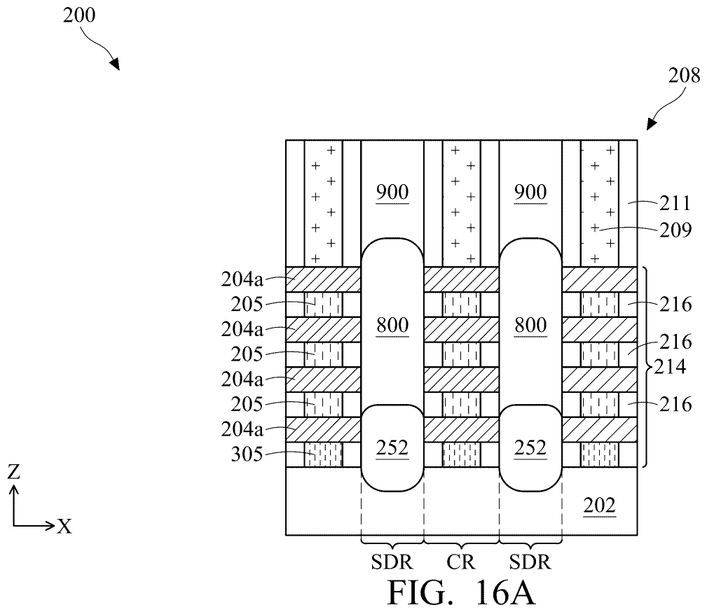

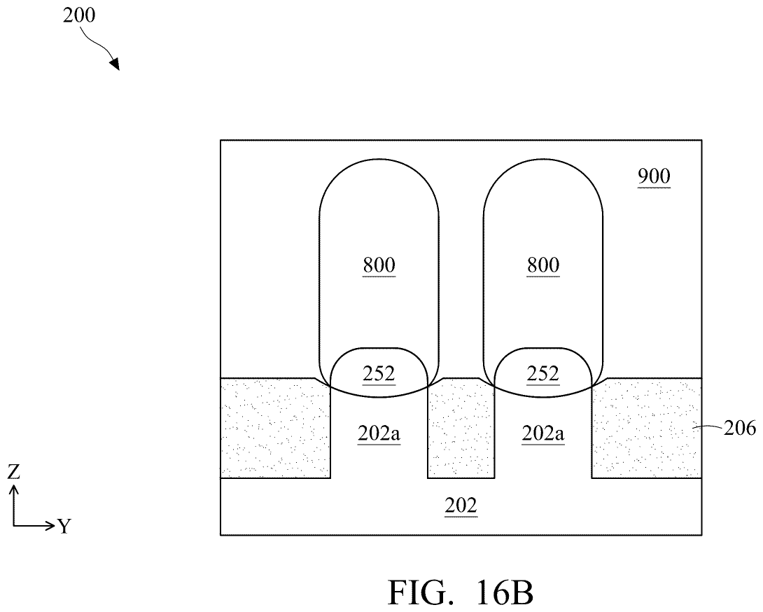

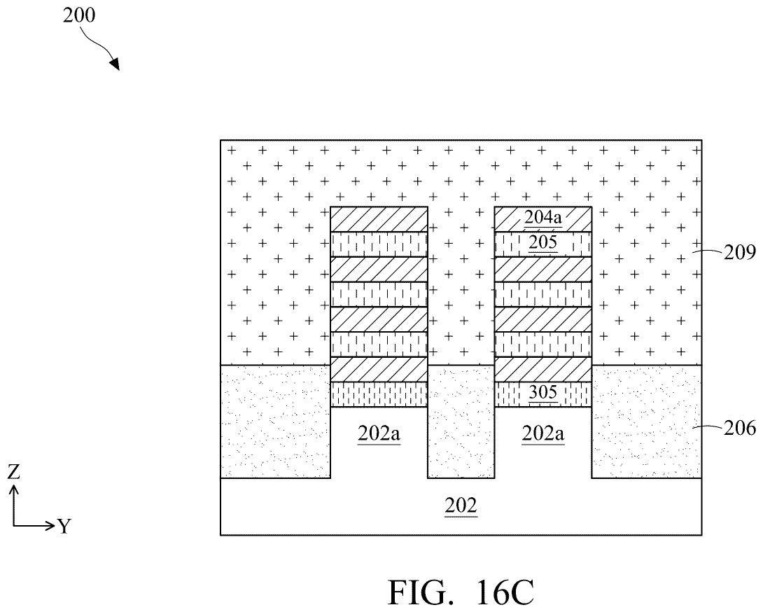

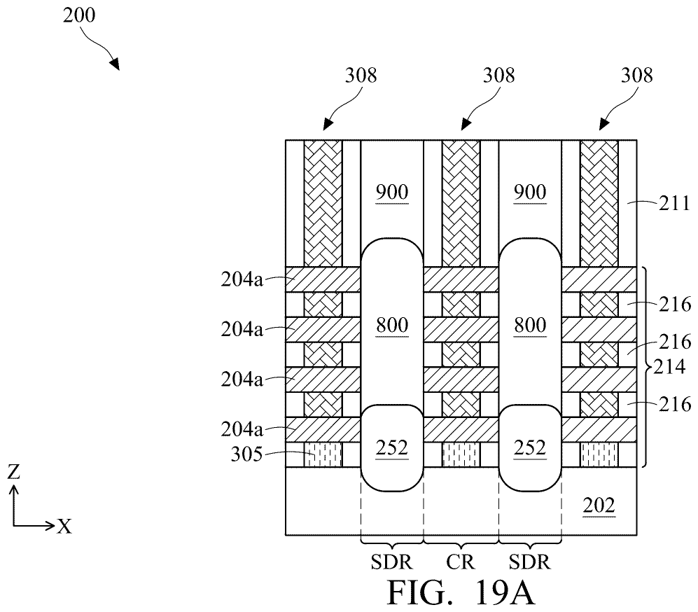

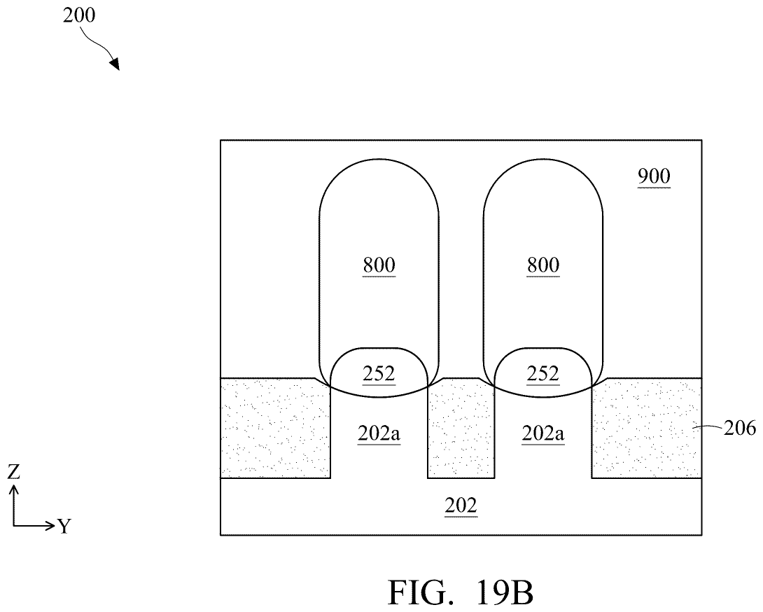

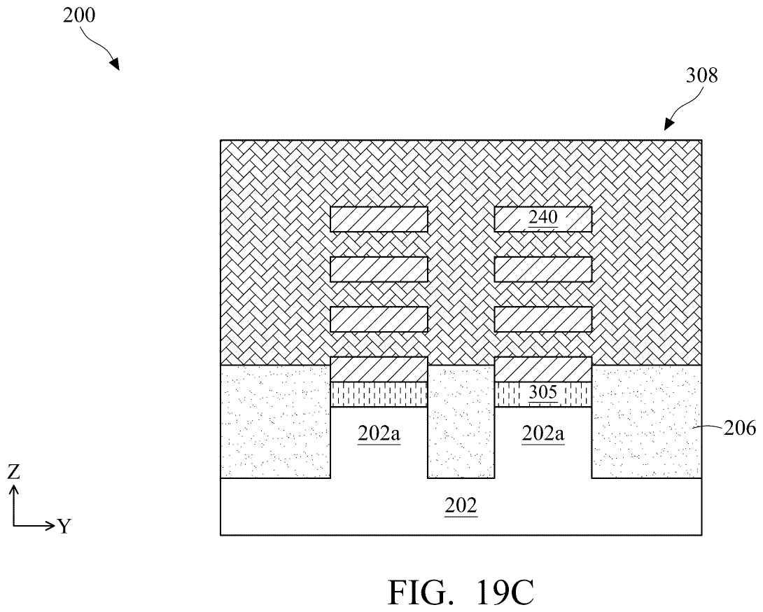

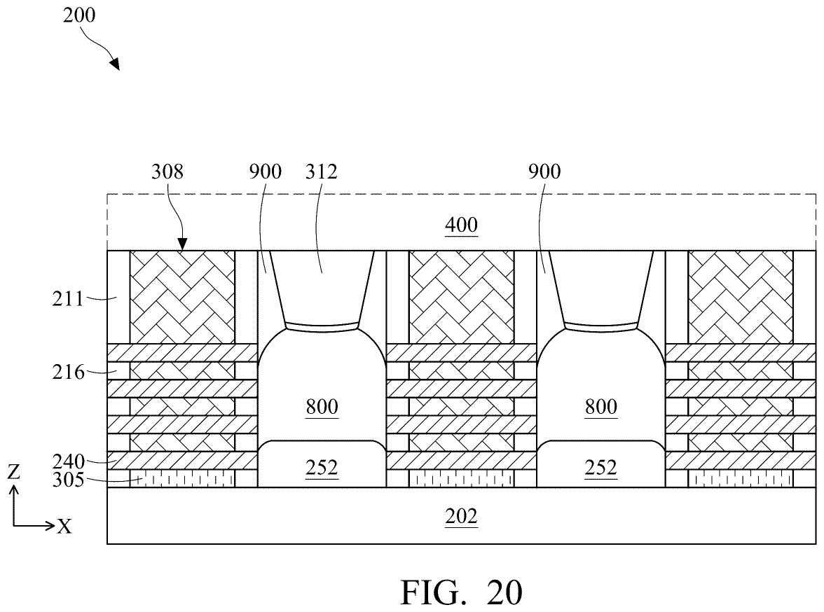

FIG. 7 illustrates a three-dimensional view of a semiconductor workpiece 250 having a buried dummy semiconductor layer 214a below an isolation structure 206 and with lines A-A′, B-B′, and C-C′ cut across the semiconductor workpiece 250. The semiconductor workpiece 250 corresponds to the semiconductor device 200 at the end of method 100 (e.g., at the stage illustrated in FIG. 5A or 5B), or at some fabrication stage after the method 100 (e.g., after formation of the dummy gates). The line A-A′ cuts lengthwise in the x direction along a semiconductor fin 215 and across multiple dummy gate structures 208. The line B-B′ cuts lengthwise in the y direction across multiple source/drain regions (SDR) of the semiconductor fins 215. The line C-C′ cuts lengthwise in the y direction across a dummy gate stack 209 of a dummy gate structure 208. FIGS. 8A-19A, 8B-19B, and 8C-19C illustrate cross-sectional views of a semiconductor device 200 cut along the lines A-A′, B-B′, and C-C′ respectively at intermediate stages of fabrication and processed in accordance with the method 1000 of FIGS. 6A-6B. FIGS. 14A, 14B, and 14C are at a same stage of fabrication, FIGS. 15A, 15B, and 15C are at a same stage of fabrication, FIGS. 16A, 16B, and 16C are at a same stage of fabrication, and so on. FIGS. 20-24 follows the fabrication stage of FIGS. 19A-19C. FIGS. 20-24 illustrate cross-sectional views of a semiconductor device 200 cut along the lines A-A′ at intermediate stages of fabrication and processed in accordance with the method 1000 of FIGS. 6A-6B.

Referring now to FIG. 7 and FIGS. 8A-8C collectively, the method 1000 at operation 1002 receives a workpiece 250 of a semiconductor device 200. The workpiece 250 may be formed by the method 100 previously described. The workpiece 250 includes semiconductor fins 215 with interleaved first and second semiconductor layers 204a and 204b, where the semiconductor fins 215 extends above an isolation structure 206 over a substrate 202. The semiconductor fins 215 include dummy semiconductor layers 214a below the top surface of the isolation structure 206 and functional semiconductor layers 214b above the top surface of the isolation structure 206. The dummy semiconductor layers 214a and the functional semiconductor layers 214b are different portions of semiconductor stack portions 214 of the semiconductor fins 215. The dummy semiconductor layers 214a are bottommost layers of the second semiconductor layers 204b. The functional semiconductor layers 214b are exposed and interleaved first and second semiconductor layers 204a and 204b.

Still referring to FIG. 7 and FIGS. 8A-8C, the method 1000 at operation 1004 forms dummy gate structures 208 having dummy gate stacks 209 and gate spacers 211 over channel regions CR of the semiconductor fins 215. The channel regions CR are regions of the semiconductor fins 215 underneath the dummy gate stacks 209. The source/drain (S/D) regions SDR are regions of the semiconductor fins 215 adjacent the channel regions CR and extending between the dummy gate structures 208. The semiconductor fins 215 (also referred to as active regions or fin active regions) extend lengthwise in the x direction, and the dummy gate structures 208 extend lengthwise in the y direction. Each of the dummy gate stacks 209 may be made of polysilicon and surround the functional semiconductor layers 214b of the semiconductor stack portions 214. Although not shown, the dummy gate stacks 209 may include various layers, such as dummy gate electrode layers, dummy gate dielectric layers, and/or dummy hard mask layers. The gate spacers 211 are formed along sidewalls of the dummy gate stacks 209. The gate spacers 211 may be made of silicon oxide, silicon nitride, silicon oxycarbide, silicon oxycarbonitride, silicon carbonitride, metal nitride, or a suitable dielectric material.

Referring to FIGS. 8B-8C, since the dummy gate structures 208 are disposed only over channel regions CR (and not over the S/D regions SDR), only FIG. 8C (and not FIG. 8B) shows a dummy gate stack 209 covering the semiconductor fins 215. Note that FIG. 8C illustrates a cross-sectional view that corresponds to the semiconductor device 200 in FIG. 5A or 5B, except with the dummy gate stack 209 formed thereover.

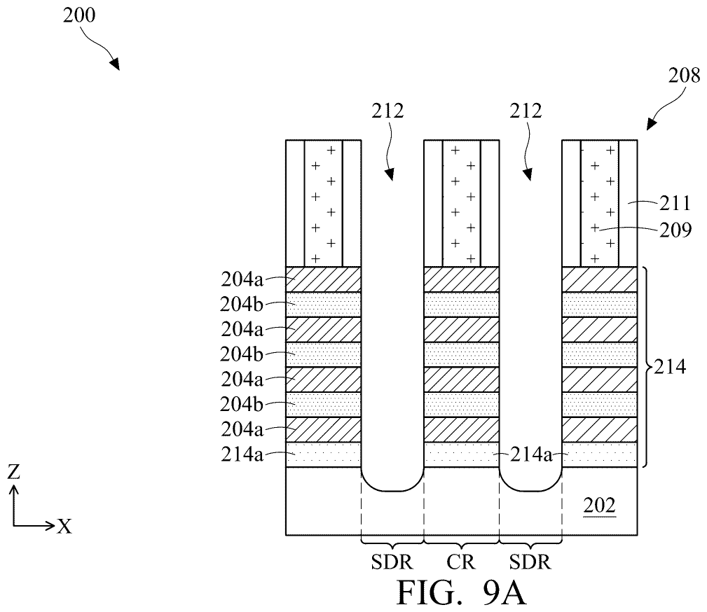

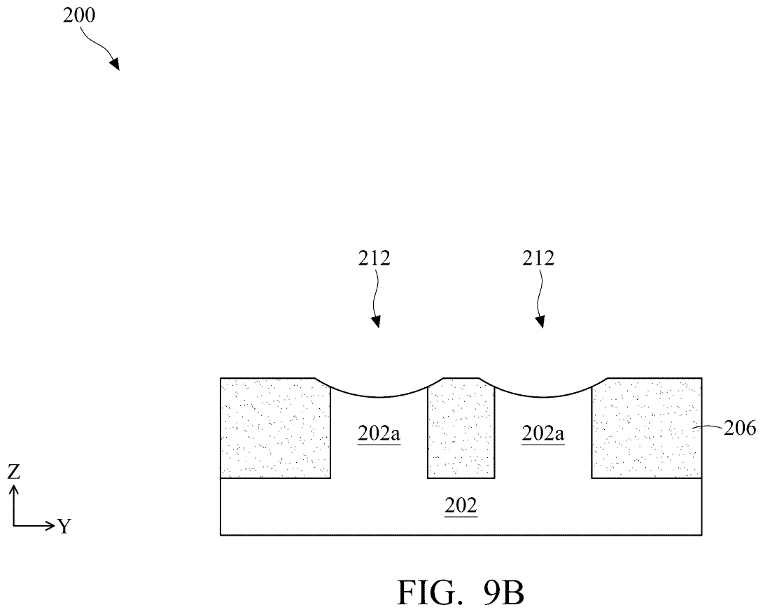

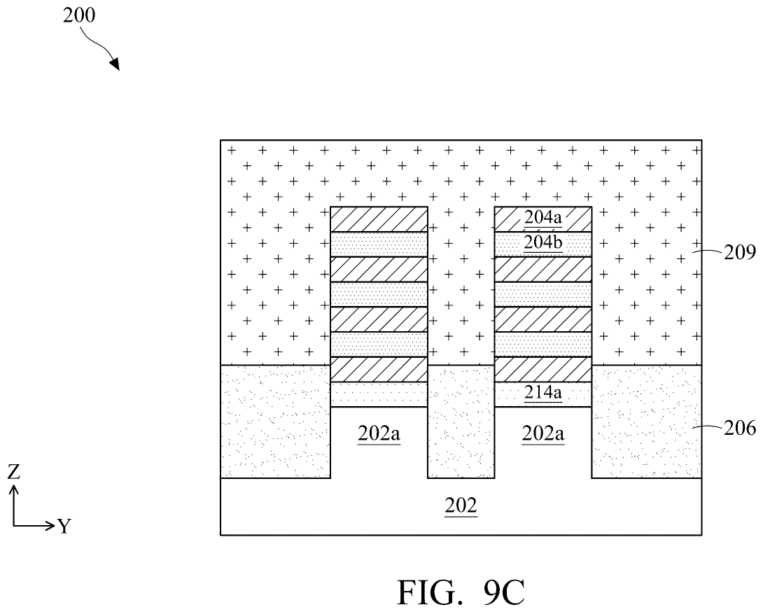

Referring now to FIGS. 9A-9C collectively, the method 1000 at operation 1006 forms S/D trenches 212 in the S/D regions SDR adjacent to the channel regions CR. The S/D trenches 212 expose side surfaces of the remaining semiconductor stack portions 214 (i.e., portions in the channel regions CR). As shown in FIG. 9Aa and 9B, the S/D trenches 212 may extend below a bottom surface of the dummy semiconductor layers 214a and below a top surface of the isolation structure 206. In the present embodiment, the S/D trenches 212 are deep trenches that expose protruding portions 202a of the substrate 202. Forming deep S/D trenches 212 may improve the backside via formation process by lowering the aspect ratio of backside via trenches. The S/D trenches 212 may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stack portions 214 with minimal (to no) etching of dummy gate structures 208 (i.e., dummy gate stacks 209 and gate spacers 211). In some embodiments, a lithography process is performed to form a patterned mask layer that covers dummy gate structures 208, and the etching process uses the patterned mask layer as an etch mask when forming the S/D trenches 212.

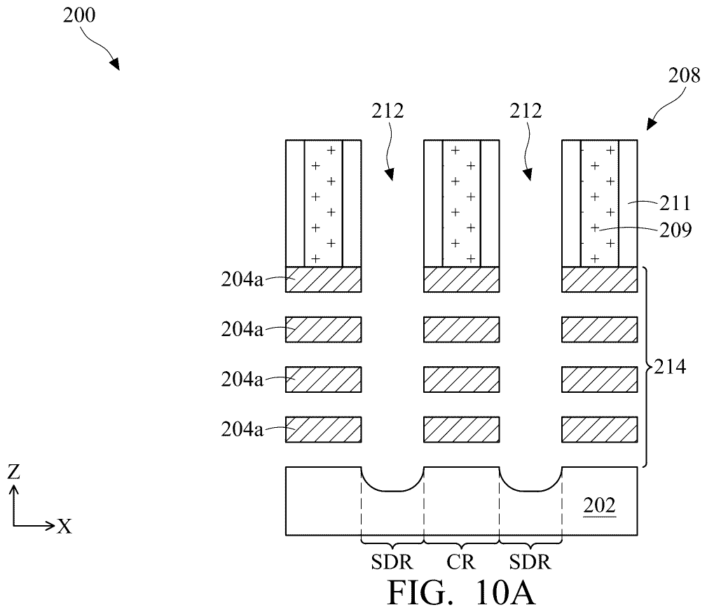

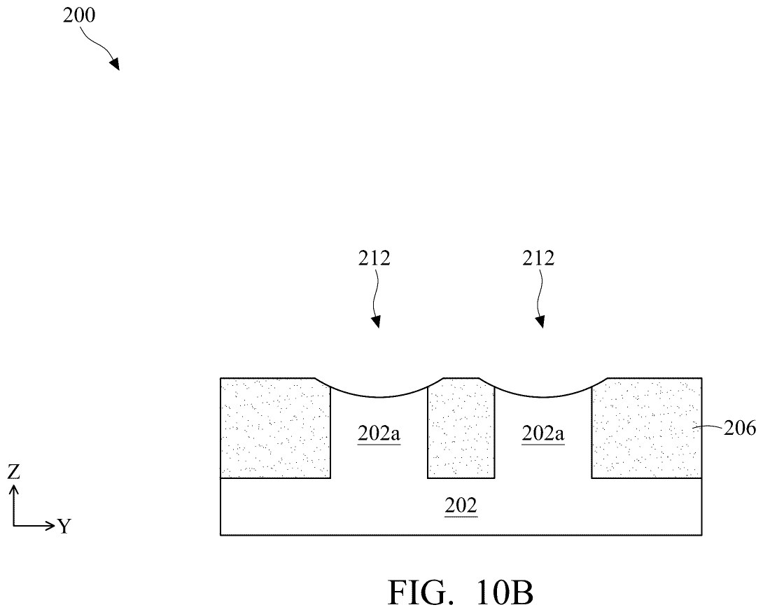

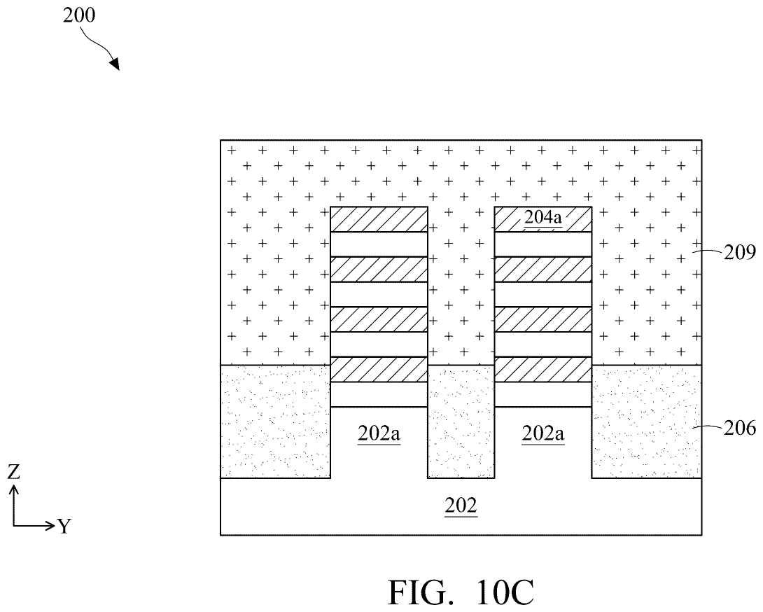

Referring now to FIGS. 10A-10C, 11A-11C, and 12A-12C collectively, the method 1000 at operation 1008 replaces all of the second semiconductor layers 204b (including the dummy semiconductor layers 214a) with interposer layers 205 and 305. The second semiconductor layers 204b of the functional semiconductor layers 214b are replaced with top interposer layers 205 and the second semiconductor layers 204b of the dummy semiconductor layers 214a are replaced with bottom interposer layers 305. The top and the bottom interposer layers 205 and 305 are of a same material composition and they are distinguished only for purposes of description.

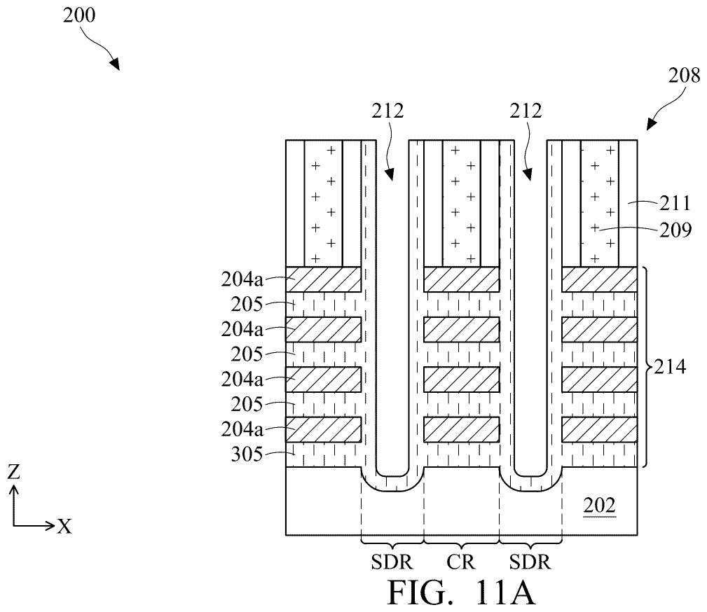

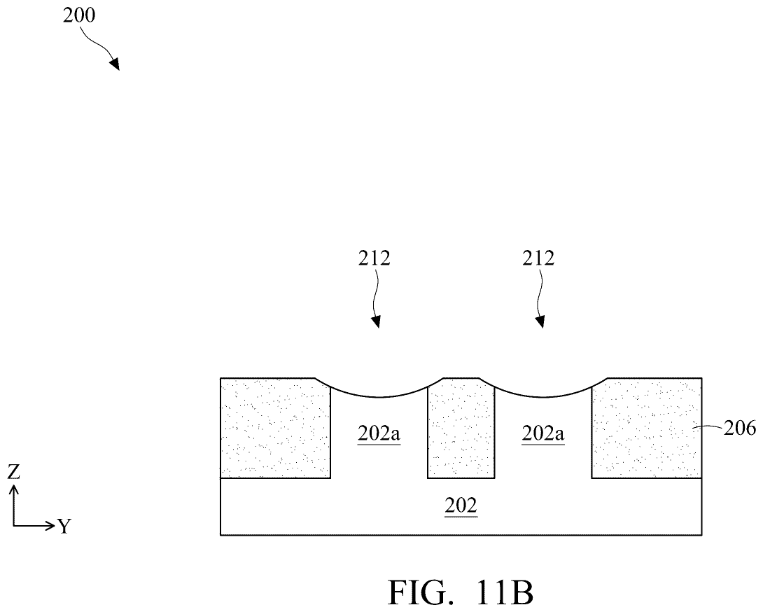

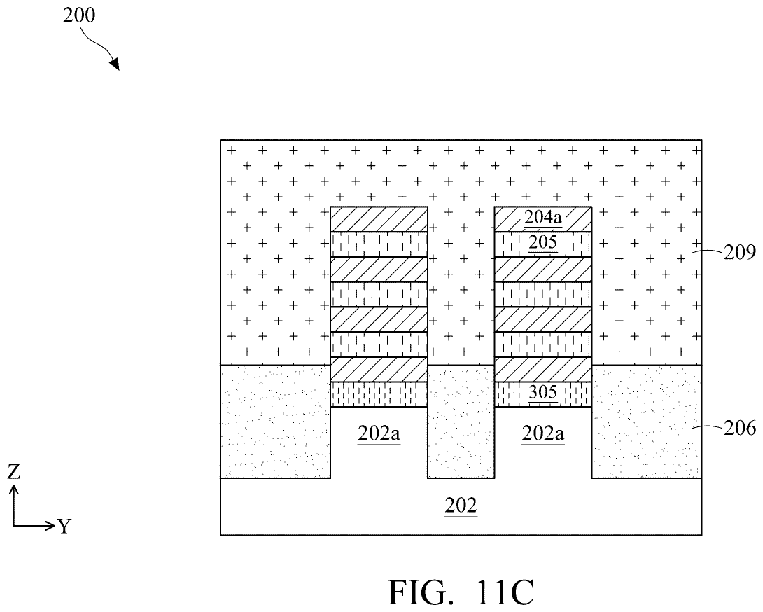

Referring to FIGS. 10A-10C collectively, the operation 1006 may include etching to completely remove all of the second semiconductor layers 204b with minimal (to no) etching of the first semiconductor layers 204a. Then, referring to FIGS. 11A-11C and 12A-12C, interposer layers 205 and 305 are formed in the space left behind by the removed second semiconductor layers 204b. The interposer layers 205 and 305 may be formed by an interposer deposition process (e.g., CVD) and an interposer etching process. For example, an interposer deposition process is performed to fill a dielectric material in the S/D trenches 212. The dielectric material seeps into the gaps left behind by the removed second semiconductor layers 204b, thereby filling in the gaps. Then, an interposer etching process is performed to selectively etch the dielectric material to form the interposer layers 205 and 305. The top interposer layers 205 will later be removed at a later channel-release stage when forming metal gates, and the bottom interposer layers 305 will remain to act as backside hard masks when forming self-aligned backside vias. The interposer etching process may be a single wet etching process that removes the dielectric material in the S/D trenches 212 and also laterally etches the dielectric material in the channel regions CR. Alternatively, the interposer etching process includes a directional dry etching process that removes the dielectric material in the S/D trenches 212 and a wet etching process that laterally etches the dielectric material in the channel regions CR. The lateral etching results in air gaps vertically between adjacent first semiconductor layers 204a.

In the present embodiment, the dielectric material of the interposer layers 205 and 305 includes silicon oxide or silicon oxycarbide (e.g., SiOₓ, SiₓC_{y}O_{z}). However, the interposer layers 205 and 305 may include other suitable dielectric materials as long as there is etchant selectivity between the interposer layers 205 and 305 and the isolation structure 206 (as previously described). In an embodiment, the interposer layers 205 includes an oxide-based dielectric such as silicon oxide. In another embodiment, the isolation layer 306 includes a non-oxide-based dielectric such as silicon nitride, silicon carbide, silicon oxynitride, or silicon carbonitride. In a further embodiment, the interposer layers 205 and 305 may be formed of a bottom anti-reflective coating (BARC) layer. The BARC layer may be formed by spin-on coating, which is a cheaper process than CVD. In some instances, the BARC layer may include silicon-containing polymers, carbon-containing polymers, or spin-on carbon (SOC). Since the interposer layers 305 will later act as a hard mask, the BARC material may be formulated with higher silicon content to provide better etch resistance.

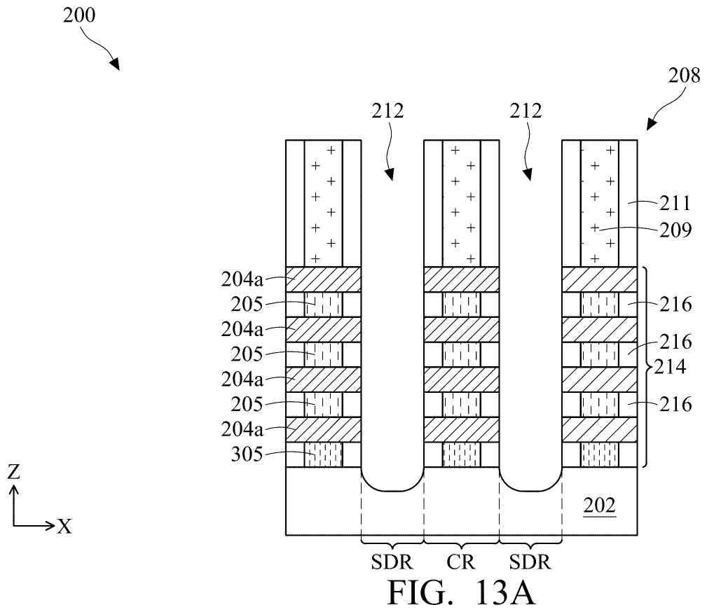

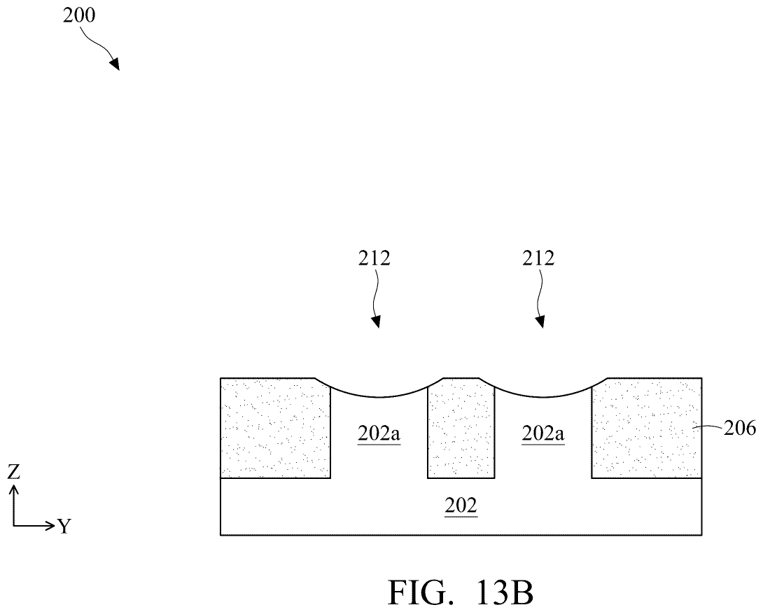

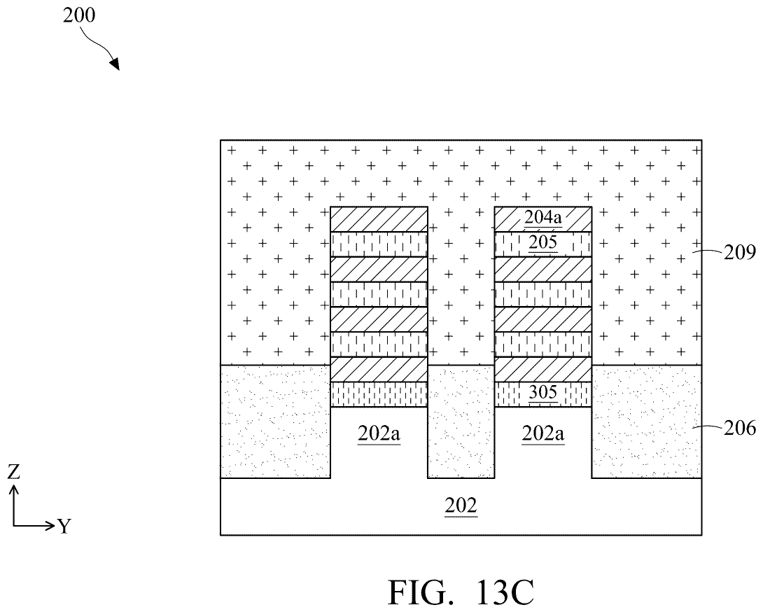

Referring now to FIGS. 13A-13C collectively, the method 1000 at operation 1010 forms inner spacers 216 adjacent to the interposer layers 205 and 305 in the channel regions CR. The inner spacers 216 may be formed by any suitable process. As previously described, a side (or lateral) etch process may be performed as part of forming the interposer layers 205 and 305. Alternatively, or additionally, a separate side etching process is performed to tune air gap width. For example, a side etch process may be performed after forming the interposer layers 205 and 305. The side etch process is performed to selectively etch sidewalls of the interposer layers 205 and 305 without etching (or substantially etching) the first semiconductor layers 204a. In other words, the side etch process is configured to laterally etch (e.g., along the x direction) interposer layers 205 and 305, thereby reducing a length of the interposer layers 205 along the x direction. After the side etch process is performed, air gaps are formed under each of the first semiconductor layers 204a. Then, inner spacers 216 are formed in each of the air gaps. The inner spacers 216 are disposed directly below the gate spacers 211, and they may be substantially vertically aligned with the gate spacers 211 along the z direction.

The inner spacers 216 may be formed by a spacer deposition process and a spacer etching process. For example, a spacer deposition process is performed to form a spacer layer over the dummy gate structures 208 and over features defining the S/D trenches 212 (e.g., semiconductor layers 204a, interposer layers 205 and 305, and substrate 202). The spacer layer partially (and, in some embodiments, completely) fills the S/D trenches 212. The spacer deposition process is configured to ensure that the spacer layer fills the air gaps between semiconductor layers 204a and between semiconductor layers 204a and substrate 202 under gate spacers 211. A spacer etching process is then performed that selectively etches the spacer layer to form inner spacers 216 as depicted in FIG. 13A with minimal (to no) etching of semiconductor layers 204a, dummy gate stacks 209, and gate spacers 211. The spacer layer (and thus inner spacers 216) includes a material that is different than a material of the semiconductor layers 204a, the gate spacers 211, and the interposer layers 205 and 305. This is to achieve desired etching selectivity during a later channel release process of removing the interposer layers 205 while keeping the semiconductor layers 204a, the gate spacers 211, and the inner spacers 216 intact. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In an embodiment, the spacer layer includes SiN, SiON, SiC, or Si₃N₄.

Referring now to FIGS. 14A-14C, the method 1000 at operation 1012 performs a substrate regrowth process in the S/D trenches 212. As shown, the substrate regrowth process forms semiconductor features 252 on the protruding portions 202a of the substrate 202. The substrate regrowth process may include selective epitaxial growth. In the present embodiment, the semiconductor features 252 provide fresh undoped silicon epitaxial layers as a seed layers for subsequent source/drain (S/D) epitaxial growth. The semiconductor features 252, as undoped silicon, can provide isolation and avoid short to adjacent active regions. Note that the semiconductor features 252 may be grown above top surfaces of the interposer layers 305 but below top surfaces of bottommost interposer layers 205.

Referring now to FIGS. 15A-15C, the method 1000 at operation 1014 epitaxially grows S/D features 800 in the S/D trenches 212 and on the semiconductor features 252. The S/D features 800 may include n-type S/D features that correspond with n-type GAA transistor regions or p-type S/D features that correspond with p-type GAA transistor regions. The S/D features 800 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 202 (or semiconductor features 252 thereof) and/or semiconductor stack portions 214 (in particular, semiconductor layers 204a). Epitaxial S/D features 800 are doped with n-type dopants and/or p-type dopants. In some embodiments, for the n-type GAA transistors, epitaxial S/D features 800 include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial S/D features 800 include silicon germanium or germanium and can be doped with boron, other p-type dopant, or combinations thereof (for example, forming Si:Ge:B epitaxial source/drain features).

In some embodiments, epitaxial S/D features 800 include materials and/or dopants that achieve desired tensile stress and/or compressive stress in respective channel regions CR. In some embodiments, epitaxial S/D features 800 are doped during deposition by adding impurities to a source material of the epitaxy process (i.e., in-situ). In some embodiments, epitaxial S/D features 800 are doped by an ion implantation process subsequent to a deposition process. In some embodiments, annealing processes (e.g., rapid thermal annealing (RTA) and/or laser annealing) are performed to activate dopants in epitaxial S/D features 800 and/or other source/drain regions (for example, heavily doped source/drain regions and/or lightly doped source/drain (LDD) regions). In some embodiments, epitaxial S/D features 800 are formed in separate processing sequences that include, for example, masking p-type GAA transistor regions when forming epitaxial S/D features 800 in n-type GAA transistor regions and masking n-type GAA transistor regions when forming epitaxial S/D features 800 in p-type GAA transistor regions.

In some embodiments (not shown), epitaxial S/D features 800 are formed to include more than one epitaxial layer. For example, each of the S/D features 800 includes an inner heavily doped layer and an outer lightly doped layer (or layers). In one embodiment, the outer lightly doped layer is first epitaxially grown in the S/D trenches 212 from side surfaces of the semiconductor layers 204a and the substrate 202 (or semiconductor features 252 thereof). Then, the inner heavily doped layer is epitaxially grown from the outer lightly doped layer to fill the S/D trenches 212. The S/D features 800 may grow to a height above the topmost first semiconductor layers 204a and between gate spacers 211 of different dummy gate structures 208. As shown in FIG. 15B, the S/D features 800 are grown over the isolation structure 206.

Referring now to FIGS. 16A-16C collectively, the method 1000 at operation 1016 forms an interlayer dielectric (ILD) layer 900 over the S/D features 800. As shown in FIG. 16A, the ILD layer 900 also fills the space between adjacent dummy gate structures 208. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 900 is formed by a flowable CVD (FCVD) process that includes, for example, depositing a flowable material (such as a liquid compound) over the device 200 and converting the flowable material to a solid material by a suitable technique, such as thermal annealing and/or ultraviolet radiation treating.

The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In the depicted embodiment, ILD layer 900 is a dielectric layer that includes a low-k dielectric material (generally referred to as a low-k dielectric layer). ILD layer 900 can include a multilayer structure having multiple dielectric materials. In some embodiments, a contact etch-stop layer (CESL) (not shown) is disposed between ILD layer 900 and the isolation structure 206, S/D features 800, and gate spacers 211. The CESL includes a material different than ILD layer 900, such as a dielectric material that is different than the dielectric material of ILD layer 900. For example, where ILD layer 900 includes silicon oxide or a low-k dielectric material, the CESL includes silicon and nitrogen, such as silicon nitride or silicon oxynitride. Subsequent to the deposition of ILD layer 900 and/or the CESL, a CMP process and/or other planarization process may be performed until reaching (exposing) a top portion (or top surface) of dummy gate stacks 209.

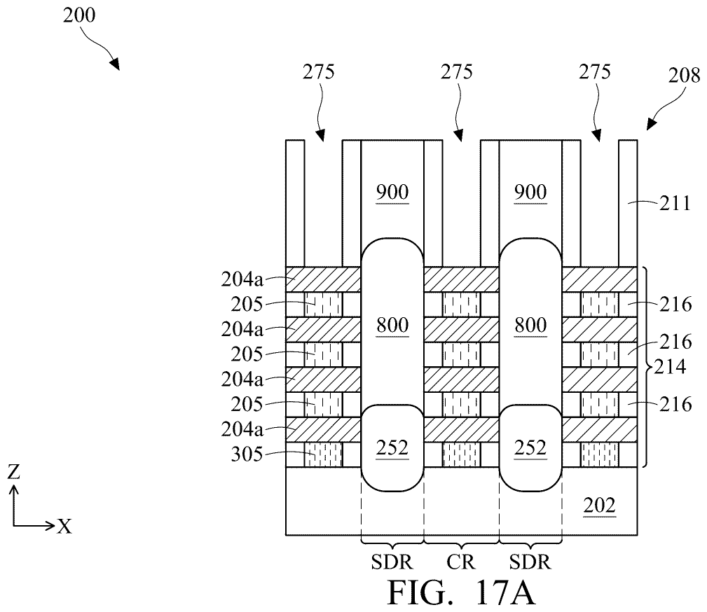

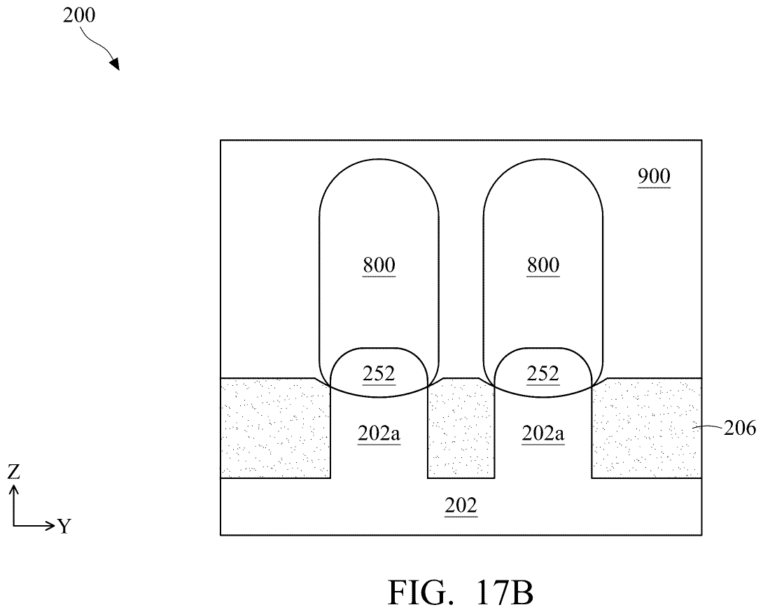

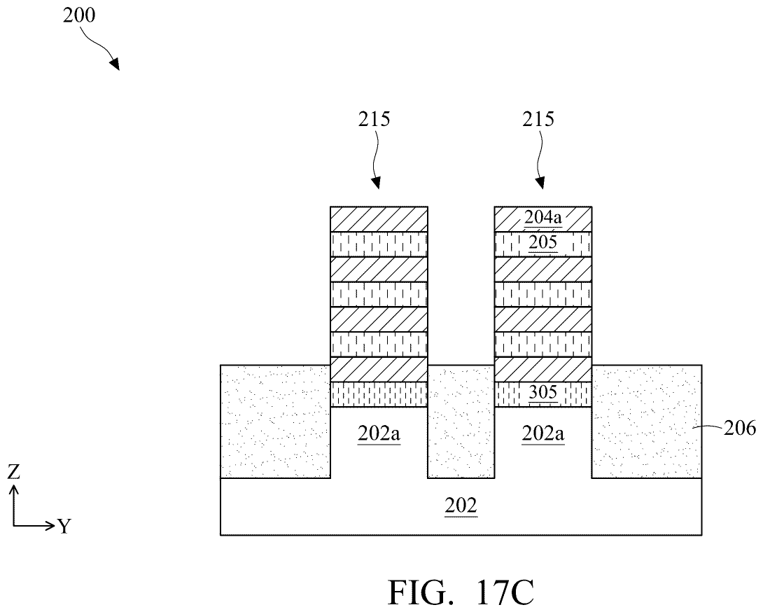

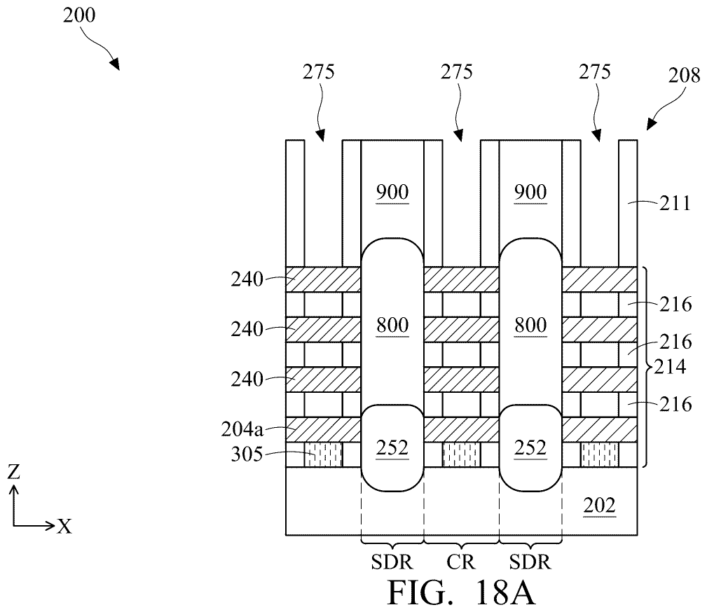

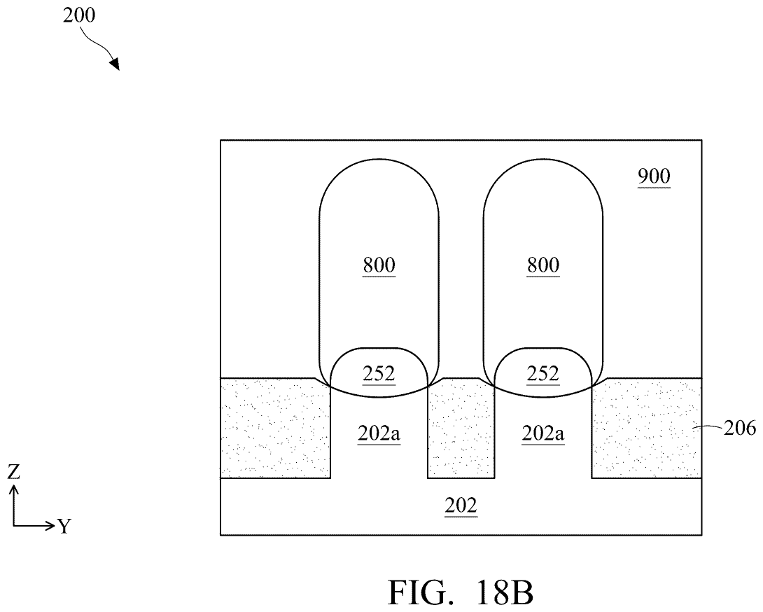

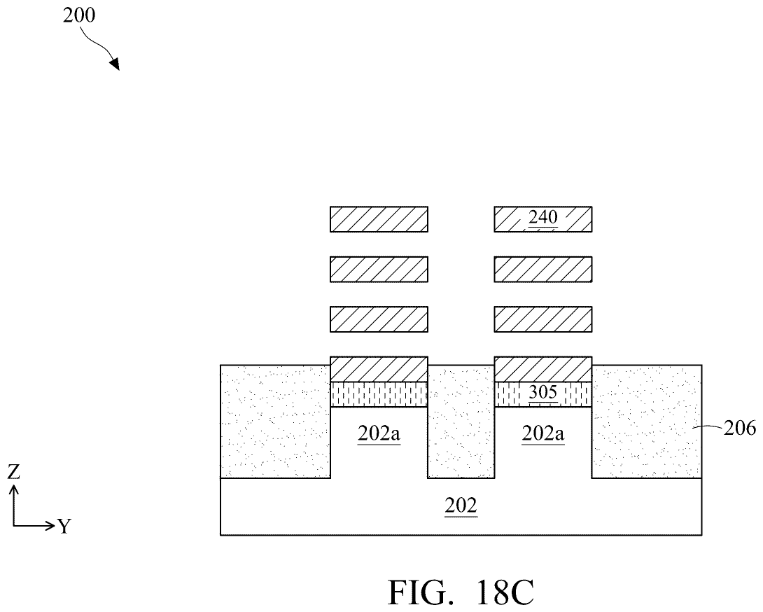

Referring now to FIGS. 17A-17C collectively, the method 1000 at operation 1018 removes dummy gate stacks 209 from the dummy gate structures 208 to expose the top interposer layers 205 without exposing the bottom interposer layers 305. The operation 1018 exposes the channel regions CR under the dummy gate stacks 209. The dummy gate stacks 209 are removed by a suitable etching process, thereby resulting in gate trenches 275 and exposing the semiconductor stack portions 214. The etching process is designed with etchant to selectively remove the dummy gate stacks 209. In the depicted embodiment, an etching process completely removes dummy gate stacks 209 to expose surfaces of the semiconductor layers 204a and the top interposer layers 205 in the y-z plane (see FIG. 18C). The etching process is a dry etching process, a wet etching process, other suitable etching process, or combinations thereof. In some embodiments, the etching process is a multi-step etch process. For example, the etching process may include alternative etchants to separately remove various layers of dummy gate stacks 209, such as dummy gate electrode layers, dummy gate dielectric layers, and/or dummy hard mask layers. In some embodiments, the etching process is configured to selectively etch dummy gate stacks 209 with minimal (to no) etching of other features of the device 200, such as ILD layer 900, gate spacers 211, semiconductor layers 204a, and interposer layers 205 and 305. In some embodiments, a lithography process is performed to form a patterned mask layer that covers ILD layer 900 and/or gate spacers 211, and the etching process uses the patterned mask layer as an etch mask.

Referring now to FIGS. 18A-18C collectively, the method 1000 at operation 1020 forms suspended semiconductor channels 240 by removing the top interposer layers 205 while the bottom interposer layers 305 remain. As shown, the interposer layers 205 (exposed by the gate trenches 275) are selectively removed from the channel regions CR. What remains of the semiconductor layers 204a now become suspended semiconductor channels 240 (except as to the bottommost semiconductor layer 204a, which is not suspended because the bottom interposer layers 305 are not removed). This removal process is also known as channel-release, and this stage of the manufacturing process is referred to as the channel-release stage. In the depicted embodiment, an etching process selectively etches interposer layers 205 with minimal (to no) etching of semiconductor layers 204a and, in some embodiments, minimal (to no) etching of isolation structure 206 and gate spacers 211 and/or inner spacers 216. Various etching parameters can be tuned to achieve selective etching of semiconductor layers 204b, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of interposer layer 205 (e.g., silicon oxide) at a higher rate than the material of semiconductor layers 204a (e.g., silicon) (i.e., the etchant has a high etch selectivity with respect to the material of interposer layers 205). The etching process is a dry etching process, a wet etching process, other suitable etching process, or combinations thereof.

Notably, referring to FIG. 18C, due to the isolation structure 206 protecting the embedded bottom interposer layers 305, the channel-release process to etch away the interposer layers 205 does not cause damage or loss to the bottom interposer layers 305. For example, in the present embodiment, the isolation structure 206 acts as an etch stop due to having a different dielectric material than that of the interposer layers 205 and 305. Without a different dielectric material for etchant selectivity, when the interposer layers 205 are etched away to form suspended semiconductor channels 240, the isolation structure 206 would also be etched, resulting in damage and risks of also etching away the bottom interposer layers 305. Having different dielectric materials ensures etchant selectivity for the structural integrity of the isolation structure 206 so that it can provide proper protection of the bottom interposer layers 305 and also between fin active regions.

Referring now to FIGS. 19A-19C collectively, the method 1000 at operation 1022 forms metal gate structures 308 over the channel regions CR and wrapping around each of the suspended semiconductor channels 240. Although not shown, each of the metal gate structures 308 may include a gate dielectric layer and a gate electrode disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches 275 and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

A planarization process is performed to remove excess gate materials from the semiconductor device 200. For example, a CMP process is performed until a top surface of the ILD layer 900 is reached (exposed) so that top surfaces of the metal gate structures 308 are substantially planar with a top surface of ILD layer 900 after the CMP process. Accordingly, the semiconductor device 200 now forms GAA transistors having metal gate structures 308 wrapping respective semiconductor channels 240 (now no longer suspended), where the metal gate structures 308 are disposed between respective semiconductor channels 240 along the z direction and between respective epitaxial S/D features 800 along the x direction. Further, the metal gate structures 308 are separated from the S/D features 800 by the gate spacers 211 and the inner spacers 216.

Referring now to FIG. 20 (which follows from FIG. 19A), the method 1000 at operation 1024 forms frontside device contacts and interconnects over the S/D features 800 and the metal gate structures 308. For example, the device contacts may include frontside S/D contacts 312 landing on the S/D features 800. The frontside S/D contacts 312 may include silicide features 311 that interface between the S/D features 800 and a fill metal of the S/D contacts 312. The frontside S/D contacts 312 may be formed through the ILD layer 900 through any suitable process. The device contacts may further include gate contacts (not shown) landing on the metal gate structures 308. The frontside S/D contacts 312 and/or gate contacts (not shown) may be part of or be connected to an interconnect structure 400. The interconnect structure 400 includes various interconnects such as interconnect metal lines and vias over and connecting to the S/D contacts 312 and gate contacts (not shown). The various interconnects connect various FETs and other devices to form an integrated circuit. The various interconnects may include copper and may be formed by one or more damascene processes. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form the various interconnects in the interconnection structure 400.

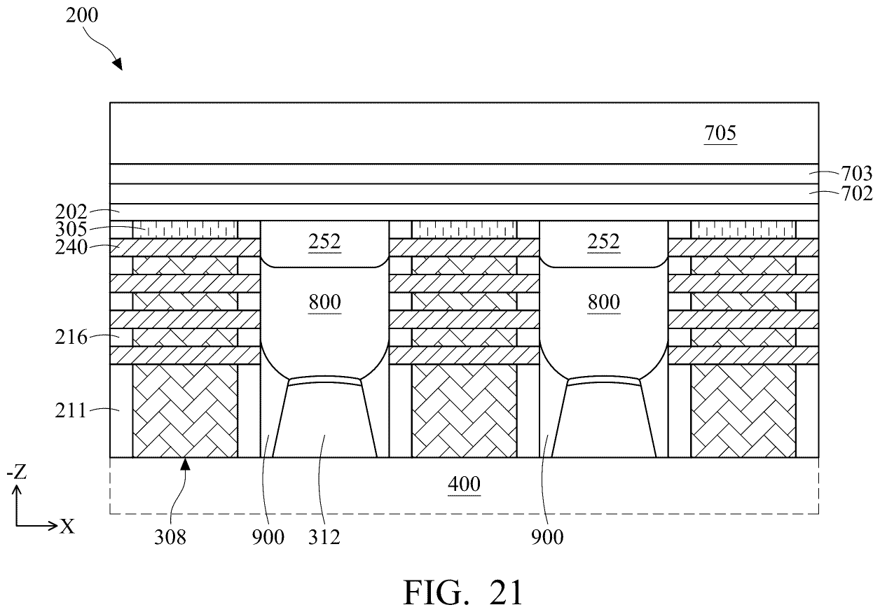

Referring now to FIGS. 21-24 (which follows from FIG. 20), the method 1000 at operation 1026 forms self-aligned backside vias 412 under the S/D features 800 using the bottom interposer layers 305 as hard mask protection layers.

Referring to FIG. 21, the workpiece is flipped for backside processing. Prior to flipping the workpiece, a carrier wafer (not shown) may be attached to the workpiece on the frontside of the interconnect structure 400. The carrier wafer provides structural support in preparation for backside processing. The workpiece is then flipped with the carrier wafer as the base and the substrate 202 on top (see FIG. 21 with flipped Z axis). Thereafter, the substrate 202 is thinned down from the backside such as through a grinding and a CMP process.

Still referring to FIG. 21, a first patterning process may be performed to define an opening for patterning one or more hard masks (e.g., hard mask layers 702 and 703). In the depicted embodiment, the first patterning process includes depositing hard mask layers 702 and 703 over the thinned-down substrate 202, depositing a photoresist layer 705 over the hard mask layers 702 and 703, and patterning the photoresist layer 705 through lithography to define an opening for patterning the hard mask layers 702 and 703. In the depicted embodiment, the hard mask layer 702 includes silicon nitride or other suitable materials to define an etch stop layer for subsequent backside processes. In an embodiment, the hard mask layer 702 includes SiN, SiON, SiC, or Si₃N₄. The hard mask layer 703 includes silicon oxide to act as a better glue layer for depositing the photoresist layer 705 thereon.

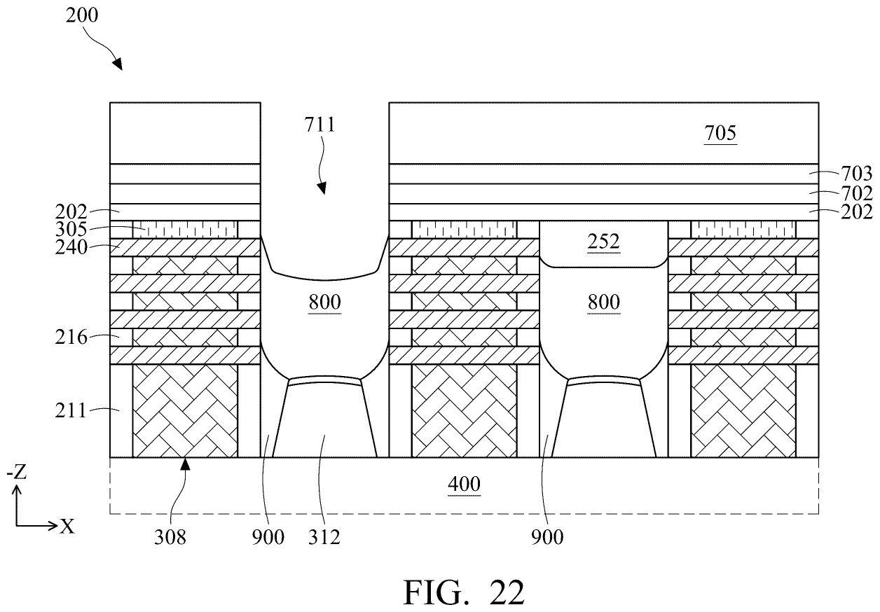

Now referring to FIG. 22, a second patterning process may be performed to pattern the hard mask layers 702 and 703 by using the patterned photoresist layer 705 as an etch mask. As shown, the opening in the patterned photoresist layer 705 is transferred to the patterned hard mask layers 702 and 703 through a first etching. Thereafter, a via trench 711 is formed by a second etching through the opening using the patterned hard mask layers 702 and 703 as an etch mask. In the depicted embodiment, the via trench 711 penetrates through the substrate 202 to expose a back side of the S/D features 800 (i.e., the opening is aligned with the corresponding S/D feature 800 from a back side). The formation of the via trench 711 may include a highly selective and isotropic etching process. For example, the etching process may be highly selective in etching the substrate 202 while highly selective against etching the bottom interposer layers 305. In this way, the bottom interposer layers 305 act as back side hard masks to protect the metal gate structures 308 and to guide the etching of the via trench 711 for forming self-aligned backside vias. Specifically, the bottom interposer layers 305 protect against vertical and lateral over-etch of the substrate 202 and/or inner spacers 216 that may cause backside via and metal gate leakage in either poor overlay shift conditions or cases of backside vias having a large critical dimension (CD).

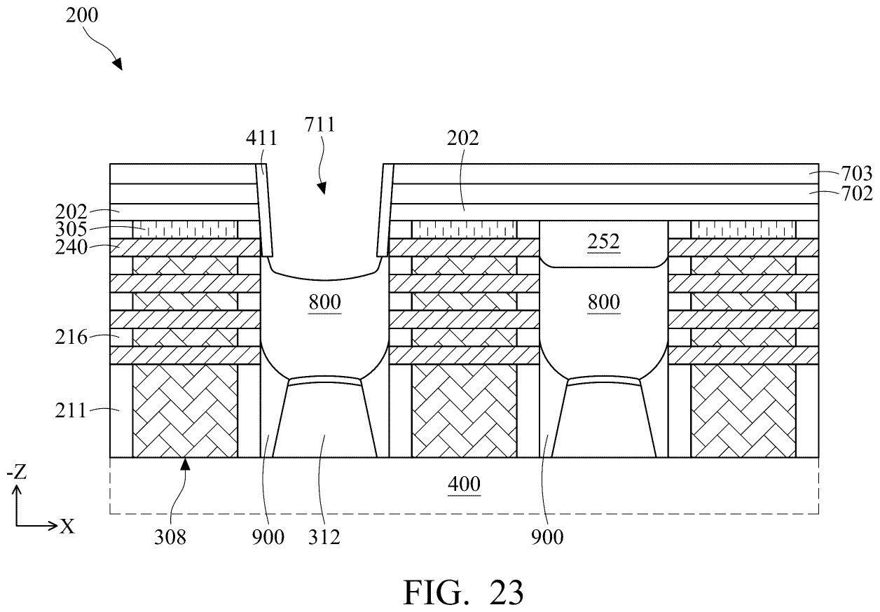

Now referring to FIG. 23, the patterned photoresist layer 705 may be removed during the second etching to form the via trench 711. Alternatively, or additionally, a stripping or ashing process may be performed to remove the patterned photoresist layer 705, thereby exposing a top surface of the hard mask layer 703. Thereafter, dielectric barrier layers 411 may be formed along sidewalls of the via trench 711. The dielectric barrier layers 411 may be formed by first conformally depositing a barrier layer in the via trench 711, then etching bottom portions of the barrier layer to expose the S/D features 800. The dielectric barrier layers 411 may include silicon nitride and/or other suitable materials to prevent unwanted diffusion or oxidation between the later formed backside via and surrounding features (e.g., metal to silicon diffusion). In the present embodiment, the dielectric barrier layers 411 includes SiN, SiON, SiC, or Si₃N₄.

Now referring to FIG. 24, a backside via 412 is formed in the via trench 711. The backside via 412 may be formed by depositing one or more conductive materials (in the via trench 711 and performing a CMP process to planarize the surface and remove excessive deposited conductive material. The conductive material may include tungsten (W), ruthenium (Ru), cobalt (Co), or combinations thereof. In an embodiment, a silicide layer (e.g., silicide features 311) is formed between the conductive material and the back side of the S/D feature 800. In the depicted embodiment, a CMP process removes the hard mask 703 and planarizes the surface such that horizontal surfaces of the hard mask layer 702, the dielectric barrier layers 411, and the backside via 412 are coplanar.

The backside via 412 is self-aligned due to adjacent bottom interposer layers 305 providing etch stop protection and defining an aligned opening to guide the formation of the via trench 711. As such, overlay shift errors that cause misalignment between the backside via 412 and the S/D feature 800 will not cause leakage and bridging issues therebetween. Further, the opening for forming the via trench 711 may be enlarged due to the self-alignment to ensure enough surface contact between the backside via 412 and the S/D feature 800.

The method 1000 may perform further steps to complete fabrication of the semiconductor device 200. Additional operations can be provided before, during, and after method 1000. Further, some of the operations described can be moved, replaced, or eliminated for additional embodiments of method 1000. In an embodiment, the method 1000 may form additional backside vias 412 (concurrently or non-concurrently with the backside via 412 described herein). In an embodiment, the method 1000 further forms backside interconnects such as backside interconnect metal lines and vias connecting to the backside via 412. In an embodiment, the backside interconnects are disposed in a backside interconnect structure (not shown) formed on the hard mask layer 702 and on the backside via 412. The backside interconnect structure (not shown) may be formed in similar fashion as the interconnect structure 400 described herein.

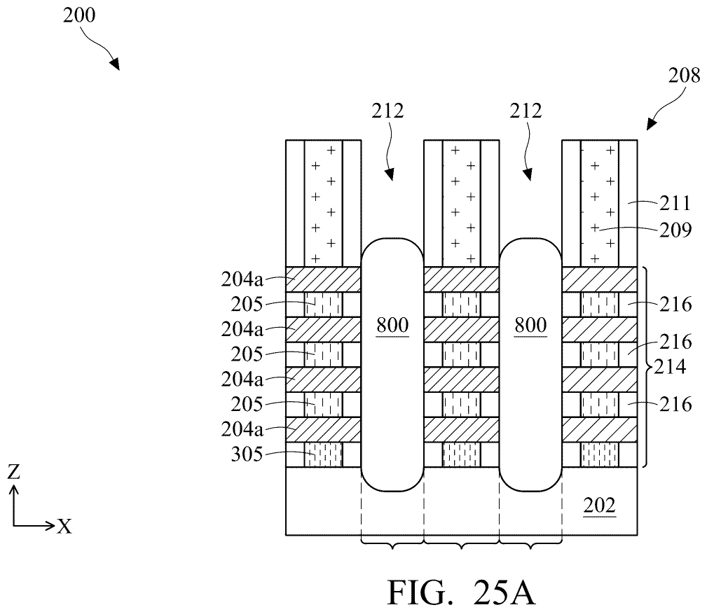

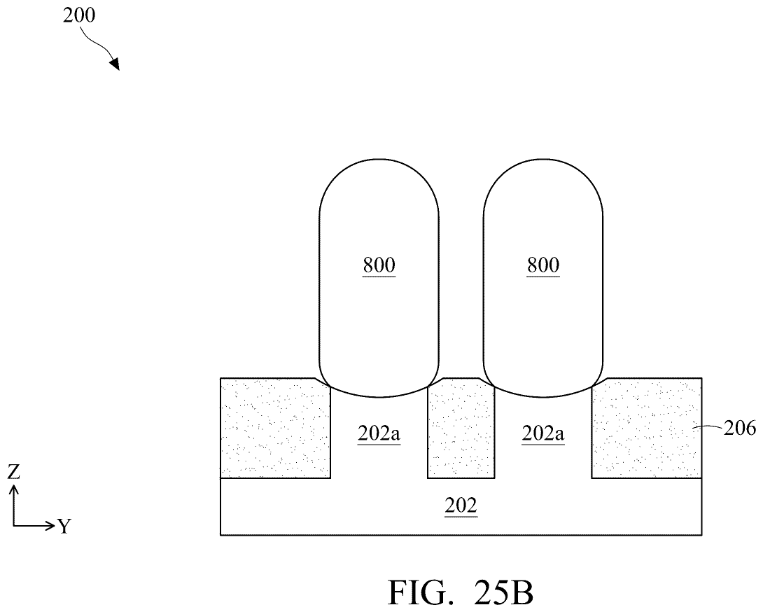

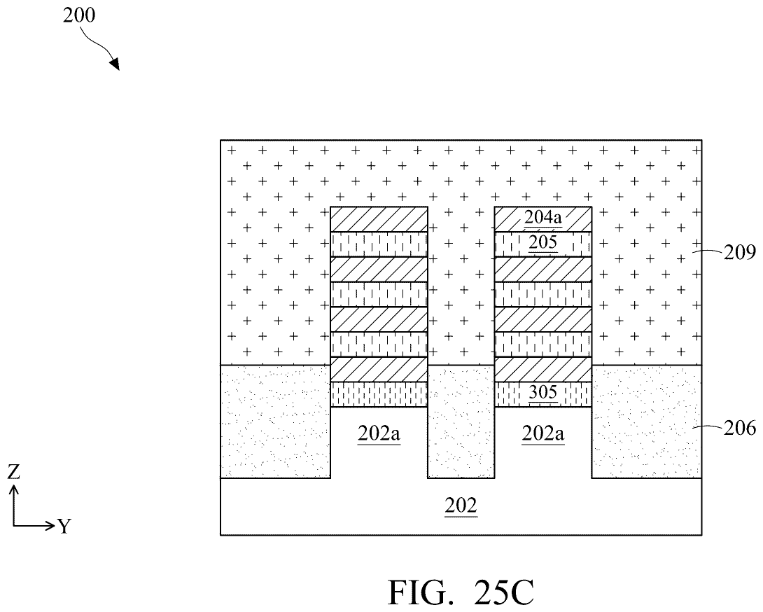

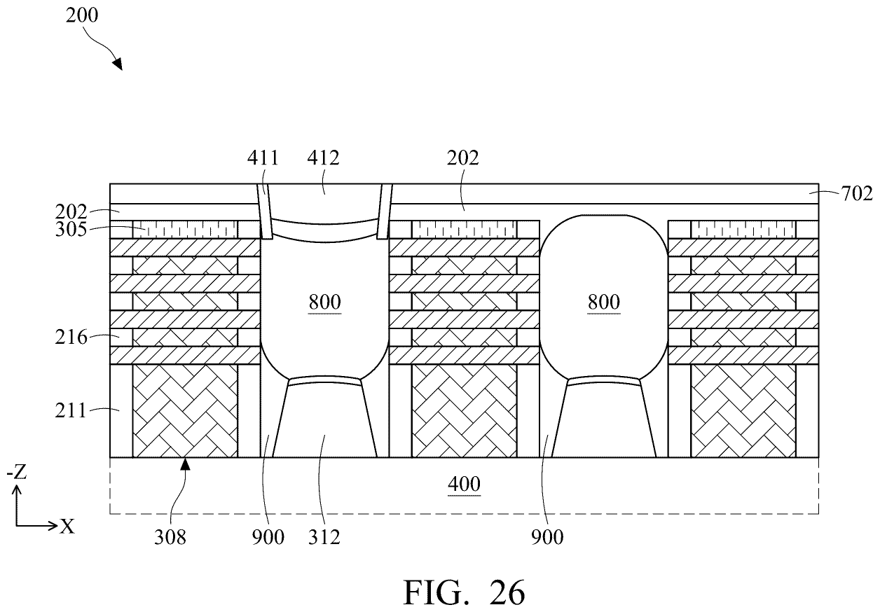

FIGS. 25A, 25B, 25C, and 26 illustrate the formation of a semiconductor device having a self-aligned backside via 412 according to another embodiment of the present disclosure. In this embodiment, the operation 1012 is omitted. In other words, there is no substrate regrowth step, and the S/D features 800 are directly grown on the substrate 202 (or protruding portions 202a thereof). As shown in FIGS. 25A-25C (which resembles FIGS. 15A-15C), the semiconductor features 252 are omitted such that the S/D features 800 extend below a bottom surface of the bottom interposer layer 305. By omitting the semiconductor features 252, deeper S/D features 800 are formed, which exhibit several advantages. One advantage is that the via trench 711 need not be as deep in order for the backside via 412 to contact the S/D feature 800. As shown in FIG. 26, the backside via 412 has a top surface below a bottom surface of the bottom interposer layer 305 (when reading in the positive Z direction). Whereas in FIG. 24, the backside via 412 has a top surface above a top surface of the bottom interposer layer 305 (when reading in the positive Z direction). By having a deeper S/D feature 800, the etch depth of the via trench 711 is reduced, and the aspect ratio of the backside via 412 is thereby improved. Another advantage of a deeper S/D feature 800 is that the backside via 412 becomes further distanced away from the metal gate structures 308, thereby resulting in better leakage current isolation.

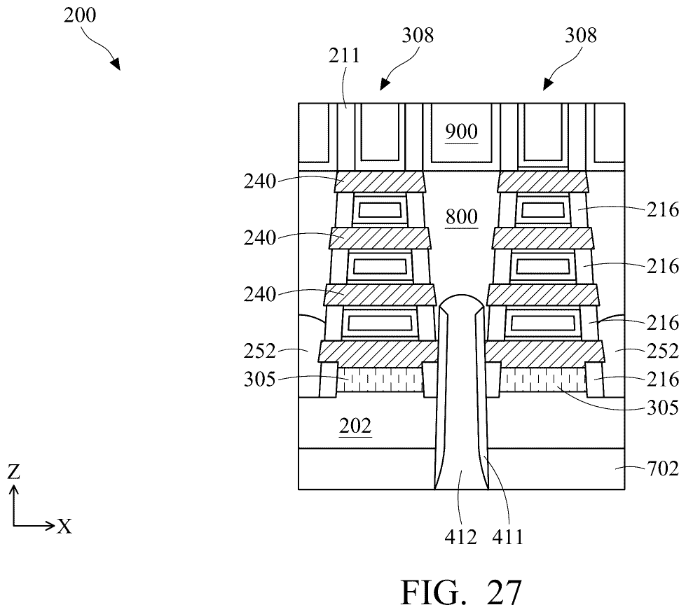

FIGS. 27-30 illustrate various embodiments of a semiconductor device 200 having a self-aligned backside via 412 using backside hard masks (i.e., bottom interposer layers 305). FIGS. 27-30 include various features previously described and some of the features will not be described again for the sake of brevity. The semiconductor devices 200 in FIGS. 27-30 are oriented in the positive Z direction and are described accordingly. Note that in each of FIGS. 27-30, the stack of semiconductor channels 240 and the portions of the metal gate structures 308 that wrap around them have a narrowing profile from top to bottom. In other words, the bottommost channel 240 is wider in the x direction than the channel 240 above it, which is then wider in the x direction than the channel 240 above it, and so on and so forth. This shape is due to the initial semiconductor fins 215 not perfectly formed due to etching anisotropy and loading effects, which causes bottom portions between etched fins to be more narrow than in top portions, especially in high aspect ratio situations (e.g., etching ions have difficulty reaching bottom of the trench due to trajectory and collisions with the sidewalls). This phenomenon is transferred and carried forward throughout fabrication, resulting in the shapes shown. Notably, because of this, the bottom interposer layers 305 have a greater width along the x direction than any of the semiconductor channels 240 above it. As shown, the bottom interposer layers 305 are also then wider than the widest portions of the metal gate structures 308. This is advantageous so that the bottom interposer layers 305 can completely cover and protect the metal gate structures 308 from the backside to prevent etching damage when forming the backside via trenches 711.

Referring now to FIG. 27, the semiconductor device 200 has a backside via 412 aligned with an S/D feature 800 and penetrating between two adjacent bottom interposer layers 305. In this embodiment, the operation 1012 (i.e., substrate regrowth) was performed. As such, the backside via 412 has to penetrate deeper to reach the S/D feature 800 (i.e., through the substrate 202 and through the semiconductor features 252). The backside via 412 penetrates past the bottom interposer layers 305. In some embodiments (like as shown), the backside via 412 also penetrates past a bottom portion of the metal gate structures 308. Because of this, in the embodiment shown, the backside via 412 has a greater height in the z direction than that of the S/D features 800.

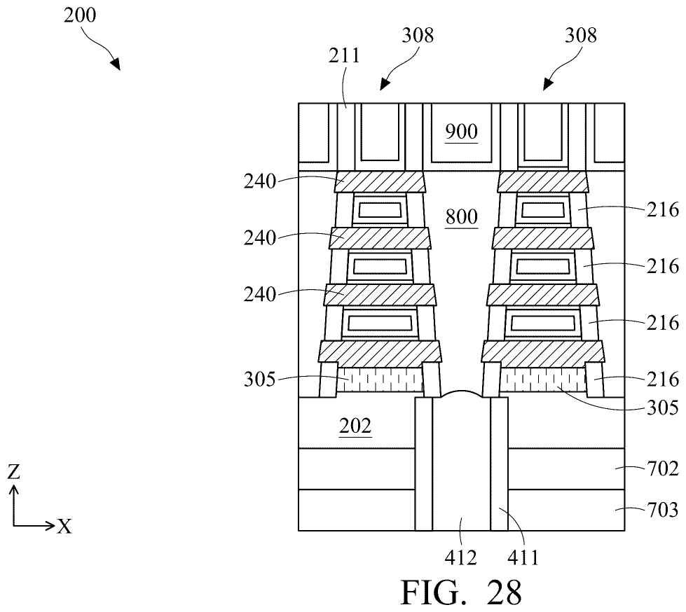

Referring now to FIG. 28, the semiconductor device 200 has a backside via 412 aligned with an S/D feature 800. In this embodiment, the operation 1012 (i.e., substrate regrowth) was omitted. As such, the backside via 412 can be more shallow and reaches the S/D feature 800 sooner. As shown, the backside via 412 only needs to penetrate through the thinned down substrate 202 and can stop on the bottom interposer layers 305. The backside via 412 does not penetrate past the bottom interposer layers 305. Because of this, in the embodiment shown, the backside via 412 has a smaller height in the z direction than that of the S/D features 800. In the embodiment shown, due to a more shallow via, the hard mask 703 may remain in the final structure and is not removed as part of CMP. This gives the backside via 412 a greater height than if the hard mask layer 703 is removed, which may improve contact resistance.

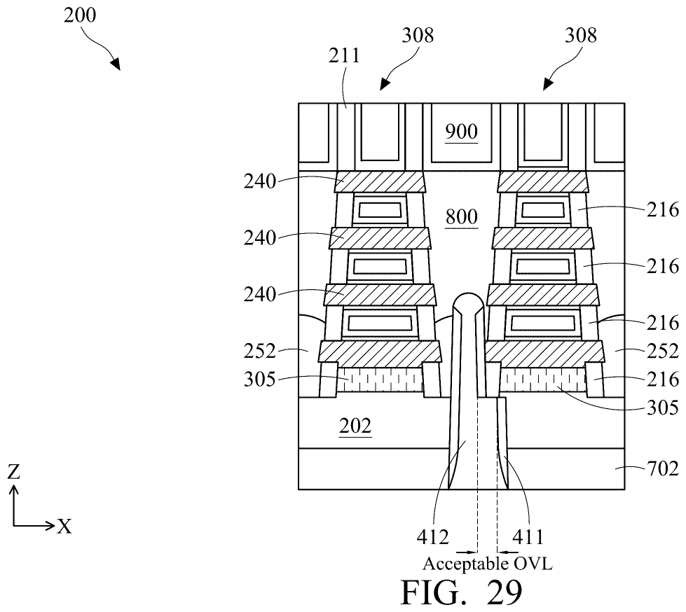

Referring now to FIG. 29, the semiconductor device 200 has a backside via 412 that is misaligned with an S/D feature 800. However, due to the bottom interposer layers 305, the misalignment does not destroy the device as long as the misalignment is within an acceptable overlay window (OVL). The bottom interposer layers 305 protects against etching too close to the metal gate structures 308. So as long as enough of the backside via 412 contacts the S/D feature 800, the device remains in good operating condition. In an embodiment, as long as there is 50% surface contact between the S/D feature 800 and the backside via 412, the misalignment is acceptable. In an embodiment, the acceptable overlay window is between about 0 nm to about 20 nm.

Still referring to FIG. 29, when there is misalignment, the etching to form the backside via trench 711 may also cause one or more of the inner spacers 216 to be slightly etched. This is because although the etchant is selected to selectively etch the substrate 202, it is chosen to minimally etch the bottom interposer layers 305, which may still slightly etch the inner spacers 216 due to different dielectric materials between the bottom interposer layers 305 and the inner spacers 216.

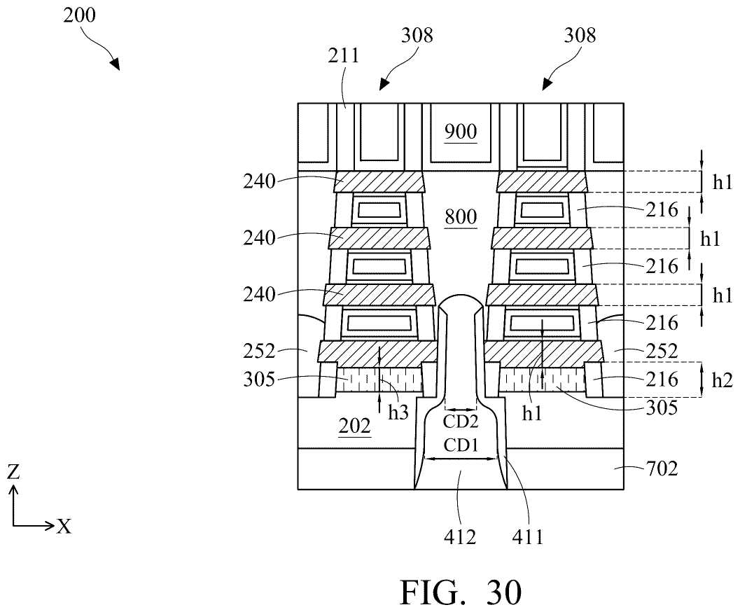

Referring now to FIG. 30, the semiconductor device 200 has a backside via 412 with an enlarged critical dimension. The backside via 412 can be enlarged without risks of etching damage to the metal gate structure 308 because the bottom interposer layers 305 act as backside protection hard masks to guide self-alignment with the S/D feature 800. In an embodiment, the enlarged backside via 412 induces 20% to 50% backside via resistance improvement. As shown, the backside via 412 has a bottom critical dimension CD1 and a top critical dimension CD2. The critical dimension CD1 refers to the critical dimension of the backside via 412 below the interposer layers 305 and along the x direction. The critical dimension CD2 refers to the critical dimension of the backside via 412 laterally between and/or above the interposer layers 305 and along the x direction. In an enlarged backside via 412 as shown, the critical dimension CD1 is greater than the top dimension CD2. In cases where the backside via 412 is not enlarged (e.g., as shown in FIGS. 27-29), the critical dimension CD1 is substantially similar to the critical dimension CD2 (e.g., both having the critical dimension CD2). In an embodiment, the critical dimension CD1 ranges between about 5 nm to about 40 nm. In an embodiment, the critical dimension CD2 ranges between about 5 nm to about 15 nm. In an embodiment, a ratio of the critical dimensions CD1 to CD2 ranges between 1 to about 3. In an embodiment, for meaningful resistance improvements, the ratio of the critical dimensions CD1 to CD2 should be at least 2.

Still referring to FIG. 30, dimensions of various other features are further described. These dimensions may equally apply to the embodiments shown in FIGS. 27-29. The semiconductor channels 240 having a height h1. The semiconductor layer above the bottom interposer layers 305 and below the metal gate structure 308 also has a height h1. In an embodiment, the height h1 is greater than about 2.5 nm. The inner spacers 216 have a height h2. In an embodiment, the height h2 is greater than the height h1. In an embodiment, the height h2 is greater than about 5 nm. The bottom interposer layers 305 have a height h3. In an embodiment, the height h3 is about the same as the height h2 (e.g., greater than about 5 nm). In an embodiment, the dielectric barrier layers 411 have a width along the x direction ranging between about 2 nm to about 8 nm.

Although not limiting, the present disclosure offers advantages for semiconductor devices having backside vias. One example advantage is forming backside hard masks that protects gate damage during backside etching processes. Another example advantage is using the hard masks to form self-aligned backside vias with improved overlay shift windows. Another example advantage is having the backside hard masks to form enlarged backside vias to improve resistance. Another example advantage is tuning substrate regrowth to enable forming backside vias of various heights.

One aspect of the present disclosure pertains to a method of forming a semiconductor device. The method includes forming a semiconductor stack with interleaved first and second semiconductor layers over a substrate; patterning the semiconductor stack and the substrate to form semiconductor fins having semiconductor stack portions over base portions;
depositing an isolation layer over the semiconductor fins; and recessing the isolation layer to form an isolation structure laterally surrounding bottom portions of the semiconductor fins and exposing top portions of the semiconductor fins, wherein the bottom portions include dummy semiconductor layers buried in the isolation structure.

In an embodiment, the method further includes forming a hard mask layer over the recessed isolation layer to form the isolation structure, the hard mask layer and the isolation layer having different dielectric materials. In a further embodiment, the dummy semiconductor layers include silicon germanium, the isolation layer includes silicon oxide, and the hard mask layer includes silicon nitride.

In an embodiment, the first and the second semiconductor layers include different semiconductor materials, and the dummy semiconductor layers are part of the second semiconductor layers.

In an embodiment, the method further includes replacing the second semiconductor layers with top interposer layers and the dummy semiconductor layers with bottom interposer layers; forming suspended semiconductor channels with the first semiconductor layers by removing the top interposer layers while the bottom interposer layers remain; forming metal gate structures over and wrapping around the suspended semiconductor channels; and forming self-aligned backside vias contacting source/drain features adjacent the suspended semiconductor channels, the self-aligned backside vias are formed on a back side of the source/drain features using the bottom interposer layers as hard mask protection layers.

In a further embodiment, the forming of the self-aligned backside vias includes thinning down the substrate from the back side; forming a patterned hard mask on the thinned down substrate; forming backside via trenches using the patterned hard mask as an etch mask and using the bottom interposer layers as etch protection layers, the backside via trenches expose the back side of the source/drain features; and depositing metal in the backside via trenches and on the source/drain features.

In a further embodiment, the method further includes forming dielectric barrier layers along sidewalls of the backside vias. In an embodiment, portions of one or more of the backside vias are vertically aligned with portions of one or more of the bottom interposer layers. In an embodiment, one or more of the backside vias have a first width below the bottom interposer layers and a second width above the bottom interposer layers, and the first width is greater than the second width.

In an embodiment, the method further includes forming inner spacers adjacent the top interposer layers and the bottom interposer layers, the inner spacers having a different dielectric material than that of the top interposer layers and the bottom interposer layers.

In an embodiment, the bottom interposer layers and the isolation layer include different dielectric materials, and the removing of the top interposer layers include selectively etching the top interposer layers while the bottom interposer layers remain covered and protected by the isolation layer.

Another aspect of the present disclosure pertains to a method of forming a semiconductor device. The method includes receiving a workpiece having semiconductor fins over a substrate, each of the semiconductor fins include interleaved first and second semiconductor layers extending above an isolation structure and a dummy semiconductor layer below the isolation structure; forming dummy gate stacks over channel regions of the semiconductor fins; forming source/drain (S/D) trenches adjacent the channel regions, thereby exposing side surfaces of the semiconductor fins; replacing the second semiconductor layers in each of the semiconductor fins with top interposer layers and replacing the dummy semiconductor layer in each of the semiconductor fins with a bottom interposer layer; forming inner spacers adjacent to the top interposer layers and the bottom interposer layer for each of semiconductor fins; epitaxially growing S/D features in the S/D trenches; removing dummy gate stacks to expose the top interposer layers without exposing the bottom interposer layer for each of the semiconductor fins; forming suspended semiconductor channels by removing the top interposer layers while the bottom interposer layer for each of the semiconductor fins remain; forming metal gate structures over the channel regions and wrapping around each of the suspended semiconductor channels; and forming self-aligned backside vias under the S/D features using the bottom interposer layer for each of the semiconductor fins as hard mask protection layers.

In an embodiment, the replacing of the second semiconductor layers include etching to remove the second semiconductor layers; depositing a dielectric material in the S/D trenches and filling in gaps left behind by the removed second semiconductor layers; and etching the dielectric material to form the top interposer layers and the bottom interposer layer.

In an embodiment, the etching of the dielectric material includes a single wet etching process that removes the dielectric material in the S/D trenches and also laterally etches the dielectric material in the channel regions.

In an embodiment, the etching of the dielectric material includes a dry etching process that removes the dielectric material in the S/D trenches and a wet etching process that laterally etches the dielectric material in the channel regions.

In an embodiment, the method further includes performing a silicon re-growth in the S/D trenches before epitaxially growing the S/D features.

Another aspect of the present disclosure pertains to a semiconductor device. The semiconductor device includes a first stack of semiconductor channels over a substrate and wrapped around by a first metal gate; a second stack of semiconductor channels over the substrate wrapped around by a second metal gate; a source/drain (S/D) feature laterally disposed between the first and the second stacks; a first hard mask layer below the first metal gate; a second hard mask layer below the second metal gate; and a backside via penetrating the substrate from a backside of the substrate and landing on a bottom surface of the S/D feature, the backside via penetrates between the first and the second hard mask layers.

In an embodiment, the semiconductor device further includes a first silicon spacer layer separating the first hard mask layer from the first metal gate; and a second silicon spacer layer separating the second hard mask layer from the second metal gate.

In an embodiment, the first and second hard mask layers have a greater width than the semiconductor channels in the first stack and the second stack of semiconductor channels.

In an embodiment, the backside via has a smaller width laterally between the first and the second hard mask layers than a width below the first and the second hard mask layers.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming a semiconductor stack with interleaved first and second semiconductor layers over a substrate;
patterning the semiconductor stack and the substrate to form semiconductor fins having semiconductor stack portions over base portions;
depositing an isolation layer over the semiconductor fins; and
recessing the isolation layer to form an isolation structure laterally surrounding bottom portions of the semiconductor fins and exposing top portions of the semiconductor fins, wherein the bottom portions include dummy semiconductor layers buried in the isolation structure.

2. The method of claim 1, further comprising:
forming a hard mask layer over the recessed isolation layer to form the isolation structure, the hard mask layer and the isolation layer having different dielectric materials.

3. The method of claim 2, wherein the dummy semiconductor layers include silicon germanium, the isolation layer includes silicon oxide, and the hard mask layer includes silicon nitride.

4. The method of claim 1, wherein the first and the second semiconductor layers include different semiconductor materials, and the dummy semiconductor layers are part of the second semiconductor layers.

5. The method of claim 1, further comprising:
replacing the second semiconductor layers with top interposer layers and the dummy semiconductor layers with bottom interposer layers;
forming suspended semiconductor channels with the first semiconductor layers by removing the top interposer layers while the bottom interposer layers remain;
forming metal gate structures over and wrapping around the suspended semiconductor channels; and
forming self-aligned backside vias contacting source/drain features adjacent the suspended semiconductor channels, the self-aligned backside vias are formed on a back side of the source/drain features using the bottom interposer layers as hard mask protection layers.

6. The method of claim 5, wherein the forming of the self-aligned backside vias includes:
thinning down the substrate from the back side;
forming a patterned hard mask on the thinned down substrate;
forming backside via trenches using the patterned hard mask as an etch mask and using the bottom interposer layers as etch protection layers, the backside via trenches expose the back side of the source/drain features; and
depositing metal in the backside via trenches and on the source/drain features.

7. The method of claim 5, further comprising forming dielectric barrier layers along sidewalls of the backside vias.

8. The method of claim 5, wherein portions of one or more of the backside vias are vertically aligned with portions of one or more of the bottom interposer layers.

9. The method of claim 5, wherein one or more of the backside vias have a first width below the bottom interposer layers and a second width above the bottom interposer layers, and the first width is greater than the second width.

10. The method of claim 5, further comprising:
forming inner spacers adjacent the top interposer layers and the bottom interposer layers, the inner spacers having a different dielectric material than that of the top interposer layers and the bottom interposer layers.

11. The method of claim 5, wherein the bottom interposer layers and the isolation layer include different dielectric materials, and the removing of the top interposer layers include selectively etching the top interposer layers while the bottom interposer layers remain covered and protected by the isolation layer.

12. A method of forming a semiconductor device, comprising:
receiving a workpiece having semiconductor fins over a substrate, each of the semiconductor fins include interleaved first and second semiconductor layers extending above an isolation structure and a dummy semiconductor layer below the isolation structure;
forming dummy gate stacks over channel regions of the semiconductor fins;
forming source/drain (S/D) trenches adjacent the channel regions, thereby exposing side surfaces of the semiconductor fins;
replacing the second semiconductor layers in each of the semiconductor fins with top interposer layers and replacing the dummy semiconductor layer in each of the semiconductor fins with a bottom interposer layer;
forming inner spacers adjacent to the top interposer layers and the bottom interposer layer for each of semiconductor fins;
epitaxially growing S/D features in the S/D trenches;
removing dummy gate stacks to expose the top interposer layers without exposing the bottom interposer layer for each of the semiconductor fins;
forming suspended semiconductor channels by removing the top interposer layers while the bottom interposer layer for each of the semiconductor fins remain;
forming metal gate structures over the channel regions and wrapping around each of the suspended semiconductor channels; and
forming self-aligned backside vias under the S/D features using the bottom interposer layer for each of the semiconductor fins as hard mask protection layers.

13. The method of claim 12, wherein the replacing of the second semiconductor layers include:
etching to remove the second semiconductor layers;
depositing a dielectric material in the S/D trenches and filling in gaps left behind by the removed second semiconductor layers; and
etching the dielectric material to form the top interposer layers and the bottom interposer layer.

14. The method of claim 13, wherein the etching of the dielectric material includes a single wet etching process that removes the dielectric material in the S/D trenches and also laterally etches the dielectric material in the channel regions.

15. The method of claim 13, wherein the etching of the dielectric material includes a dry etching process that removes the dielectric material in the S/D trenches and a wet etching process that laterally etches the dielectric material in the channel regions.

16. The method of claim 12, further comprising performing a silicon re-growth in the S/D trenches before epitaxially growing the S/D features.

17. A semiconductor device, comprising:
a first stack of semiconductor channels over a substrate and wrapped around by a first metal gate;
a second stack of semiconductor channels over the substrate wrapped around by a second metal gate;
a source/drain (S/D) feature laterally disposed between the first and the second stacks;
a first hard mask layer below the first metal gate;
a second hard mask layer below the second metal gate; and
a backside via penetrating the substrate from a backside of the substrate and landing on a bottom surface of the S/D feature, the backside via penetrates between the first and the second hard mask layers.

18. The semiconductor device of claim 17, further comprising:
a first silicon spacer layer separating the first hard mask layer from the first metal gate; and
a second silicon spacer layer separating the second hard mask layer from the second metal gate.

19. The semiconductor device of claim 17, wherein the first and second hard mask layers have a greater width than the semiconductor channels in the first stack and the second stack of semiconductor channels.

20. The semiconductor device of claim 17, wherein the backside via has a smaller width laterally between the first and the second hard mask layers than a width below the first and the second hard mask layers.
